(19) United States
(12) Patent Application Publication
(10) Pub. No.: US 2024/0364079 A1
(43) Pub. Date: Oct. 31, 2024

(54) METHOD FOR DESIGNING PHASE MODULATION LAYER AND METHOD FOR PRODUCING LIGHT-EMITTING ELEMENT

(71) Applicant: HAMAMATSU PHOTONICS K.K., Hamamatsu-shi, Shizuoka (JP)

(72) Inventors: Kazuyoshi HIROSE, Hamamatsu-shi, Shizuoka (JP); Koyo WATANABE, Hamamatsu-shi, Shizuoka (JP); Hiroki KAMEI, Hamamatsu-shi, Shizuoka (JP)

(73) Assignee: HAMAMATSU PHOTONICS K.K., Hamamastu-shi, Shizuoka (JP)

(21) Appl. No.: 18/683,035

(22) PCT Filed: May 19, 2022
(86) PCT No.: PCT/JP2022/020857

§ 371 Date: Feb. 12, 2024

(30) Foreign Application Priority Data
Aug. 18, 2021 (JP) 2021-133627

(51) Int. Cl. H01S 5/183; H01S 5/042; H01S 5/062; H01S 5/22

(52) U.S. Cl. CPC H01S 5/18302; H01S 5/0427; H01S 5/06246; H01S 5/18305; H01S 5/222

(57) ABSTRACT

A method for designing a phase modulation layer of a light emitting element as an iPMSEL including a light emitting portion and the phase modulation layer optically coupled to the light emitting portion includes a generation step for generating a design pattern of the phase modulation layer. The phase modulation layer includes a base layer and a plurality of different refractive index regions having different refractive indices from the base layer and distributed two-dimensionally in a plane perpendicular to a thickness direction of the phase modulation layer.

### TECHNICAL FIELD

The present disclosure relates to a method for designing a phase modulation layer and a method for manufacturing a light emitting element.

### BACKGROUND ART

Semiconductor light emitting elements that output any optical images by controlling the phase distribution and intensity distribution of light emitted from a plurality of light emitting points arranged in a two-dimensional manner have been studied. One of the structures of such semiconductor light emitting elements is a structure having a phase modulation layer optically coupled to an active layer. The phase modulation layer has a base layer and a plurality of different refractive index regions having different refractive indices from the base layer, and when a virtual square lattice is set in a plane perpendicular to the thickness direction of the phase modulation layer, the center of gravity of each different refractive index region is shifted from the lattice point position of the virtual square lattice according to the optical image. Such a semiconductor light emitting element is called an S-iPM (Static-integrable Phase Modulating) laser, and outputs an optical image in any two-dimensional shape including a direction perpendicular to the main surface of the substrate on which the phase modulation layer is provided and a direction inclined with respect the direction perpendicular to the main surface. Non Patent Literature 1 describes a technology related to the S-iPM laser.

### CITATION LIST

### Non Patent Literature

Non Patent Literature 1: Yoshitaka Kurosaka et al., “Phase-modulating lasers toward on-chip integration”, Scientific Reports, 6:30138 (2016)

### SUMMARY OF INVENTION

### Technical Problem

The semiconductor light emitting element described above can be applied to 3D measurement, for example. When the semiconductor light emitting element described above is applied to 3D measurement, it is conceivable to emit an optical image having a sinusoidal striped pattern. In this case, in order to improve the accuracy of 3D measurement, it is desirable to emit an optical image having a pattern with reduced noise. On the other hand, there is a demand for noise reduction without being limited to the 3D measurement and the striped pattern.

It is an object of the present disclosure to provide a method for designing a phase modulation layer and a method for manufacturing a light emitting element that make it possible to reduce noise.

### Solution to Problem

A method for designing a phase modulation layer according to the present disclosure is a method for designing a phase modulation layer of a light emitting element as an iPMSEL including a light emitting portion and the phase modulation layer optically coupled to the light emitting portion. The method for designing a phase modulation layer includes a generation step for generating a design pattern of the phase modulation layer. The phase modulation layer includes a base layer and a plurality of different refractive index regions having different refractive indices from the base layer and distributed two-dimensionally in a plane perpendicular to a thickness direction of the phase modulation layer. The generation step includes: a first step of generating a first design pattern that is a pattern for designing the different refractive index regions so that a distribution of the different refractive index regions becomes a distribution according to an optical image output from the light emitting element and that includes bright spots corresponding to bright spots of the optical image; and a second step of generating a second design pattern from the first design pattern by dividing the first design pattern generated in the first step into a plurality of regions and thinning out at least one of a plurality of bright spots included in each of the regions.

In this design method, when designing the phase modulation layer of the light emitting element that is an iPMSEL (Static-integrable Phase Modulating Surface Emitting Lasers), first, the first design pattern, which is a pattern for designing the different refractive index regions so that the distribution of the different refractive index regions of the phase modulation layer becomes a distribution according to an optical image output from the light emitting element and includes bright spots corresponding to the bright spots of the optical image, is generated. Then, by dividing the first design pattern into a plurality of regions and thinning out at least one of a plurality of bright spots included in each of the regions, a second design pattern is generated from the first design pattern. By forming the phase modulation layer based on the second design pattern generated in this manner, it is possible to reduce noise in the optical image output from the light emitting element. One of the reasons for this is thought to be that, by thinning out the bright spots on the design pattern, interference between adjacent bright spots in the actual optical image can be avoided.

In the method for designing a phase modulation layer according to the present disclosure, the first design pattern may be a pattern on a wave number space corresponding to the optical image. In the second step, four bright spots two-dimensionally adjacent to each other on the wave number space may be set as the one region, and the second design pattern may be generated by thinning out two of the four bright spots.

Alternatively, in the method for designing a phase modulation layer according to the present disclosure, the first design pattern may be a pattern on a wave number space corresponding to the optical image. In the second step, four bright spots two-dimensionally adjacent to each other on the wave number space may be set as the one region, and the second design pattern may be generated by thinning out three of the four bright spots. As described above, the design pattern generated in the generation step can be a pattern on the wave number space corresponding to a desired optical image output from the light emitting element. Then, when generating the second design pattern, noise can be reduced by thinning out two or three bright spots from four clustered bright spots on the wave number space. In addition, thinning-out a predetermined bright spot on the wave number space means making predetermined data forming the pattern relatively small (for example, set to 0).

In the method for designing a phase modulation layer according to the present disclosure, in the first step, in the first design pattern, a design region corresponding to 1st-order light of the optical image and a design region corresponding to −1st-order light of the optical image may be separated from each other. In this case, it is possible to further reduce noise.

A method for manufacturing a light emitting element according to the present disclosure may include: a first formation step for forming a light emitting portion on a substrate; and a second formation step for forming a phase modulation layer optically coupled to the light emitting portion based on the second design pattern generated by any of the methods for designing a phase modulation layer described above. In this case, a light emitting element capable of reducing noise can be manufactured.

In the method for manufacturing a light emitting element according to the present disclosure, in the first step, when a virtual square lattice is set in the plane, the first design pattern may be generated so that a center of gravity of each of the different refractive index regions is arranged away from a corresponding lattice point and has a rotation angle according to a phase distribution corresponding to the optical image around the lattice point and a lattice spacing a of the virtual square lattice and an emission wavelength λ of the light emitting portion satisfy conditions for M-point oscillation. In the second formation step, on a reciprocal lattice space of the phase modulation layer, in-plane wave number vectors in four directions each including a wave number spread corresponding to an angular spread of the optical image may be formed, another second phase distribution may be superimposed on a first phase distribution as the phase distribution so that a magnitude of at least one of the in-plane wave number vectors is smaller than 2π/λ, and the phase modulation layer including the plurality of different refractive index regions may be formed by using a phase distribution obtained by the superimposition. In this case, it is possible to remove 0th-order light from the optical image output from the light emitting element.

### Advantageous Effects of Invention

According to the present disclosure, it is possible to provide a method for designing a phase modulation layer and a method for manufacturing a light emitting element that make it possible to reduce noise.

### BRIEF DESCRIPTION OF DRAWINGS

FIG. 1 is a perspective view showing the configuration of a semiconductor light emitting element 1A as a light emitting device according to an embodiment of the present disclosure.

FIG. 2 is a cross-sectional view showing the stacked structure of the semiconductor light emitting element 1A.

FIG. 3 is a cross-sectional view showing the stacked structure of the semiconductor light emitting element 1A.

FIG. 4 is a plan view of a phase modulation layer 15A.

FIG. 5 is an enlarged view of a part of the phase modulation layer 15A.

FIG. 6 is a plan view showing an example in which the substantially periodic refractive index structure in FIG. 4 is applied only within a specific region of a phase modulation layer.

FIG. 7 is a diagram for explaining the relationship between an optical image obtained by imaging the output beam pattern of a semiconductor light emitting element 1A and the rotation angle distribution ϕ(x, y) in a phase modulation layer 15A.

FIG. 8 is a diagram for explaining coordinate transformation from spherical coordinates (r, θᵣₒₜ, θₜᵢₗₜ) to coordinates (ξ, η, ζ) in the XYZ Cartesian coordinate system.

FIG. 9 is a diagram for explaining points to be noted in the case of calculation using general discrete Fourier transform (or fast Fourier transform) when determining the arrangement of each different refractive index region 15b.

FIG. 10 is a plan view showing a reciprocal lattice space regarding a photonic crystal layer of a PCSEL that oscillates at the F point.

FIG. 11 is a three-dimensional perspective view of the reciprocal lattice space shown in FIG. 10.

FIG. 12 is a plan view showing a reciprocal lattice space regarding a photonic crystal layer of a PCSEL that oscillates at the M point.

FIG. 13 is a plan view showing a reciprocal lattice space regarding the phase modulation layer of an S-iPMSEL that oscillates at the τ point.

FIG. 14 is a three-dimensional perspective view of the reciprocal lattice space shown in FIG. 13.

FIG. 15 is a plan view showing a reciprocal lattice space regarding the phase modulation layer of the S-iPMSEL that oscillates at the M point.

FIG. 16 is a conceptual diagram for explaining an operation of adding a diffraction vector V having a fixed magnitude and direction to in-plane wave number vectors K6 to K9.

FIG. 17 is a diagram for schematically explaining the peripheral structure of a light line LL.

FIG. 18 is a diagram conceptually showing an example of the rotation angle distribution ϕ₂(x, y).

FIG. 19 is a diagram showing the rotation angle distribution ϕ(x, y) of the phase modulation layer 15A according to one practical example.

FIG. 20 is an enlarged view of a portion S shown in FIG. 19.

FIG. 21 shows a beam pattern (optical image) output from the semiconductor light emitting element 1A having the rotation angle distribution ϕ(x, y) shown in FIG. 19.

FIG. 22 is a schematic diagram of the beam pattern shown in FIG. 21.

FIG. 23(a) is a schematic diagram of a beam pattern, and FIG. 23(b) is a diagram showing the phase distribution of the beam pattern.

FIG. 24(a) is a schematic diagram of a beam pattern, and FIG. 24(b) is a diagram showing the phase distribution of the beam pattern.

FIG. 25(a) is a schematic diagram of a beam pattern, and FIG. 25(b) is a diagram showing the phase distribution of the beam pattern.

FIG. 26 is a conceptual diagram for explaining an operation of adding the diffraction vector V to the in-plane wave number vectors K6 to K9 in four directions excluding a wave number spread Δk.

FIG. 27 is a plan view of a phase modulation layer 15B according to a second modification example.

FIG. 28 is a diagram showing the positional relationship of different refractive index regions 15b in the phase modulation layer 15B.

FIGS. 29(a) to 29(g) are plan views showing examples of the shape of the different refractive index region 15b in the XY plane.

FIGS. 30(a) to 30(k) are plan views showing examples of the shape of the different refractive index region 15b in the XY plane.

FIGS. 31(a) to 31(k) are plan views showing other examples of the shape of the different refractive index region 15b in the XY plane.

FIG. 32 is a plan view showing another example of the shape of the different refractive index region in the XY plane.

FIG. 33 is a diagram showing the configuration of a light emitting device 1B according to a fourth modification example.

FIG. 34 is a diagram showing one step of a method for designing a phase modulation layer according to the present embodiment.

FIG. 35 is a diagram showing one step of the method for designing a phase modulation layer according to the present embodiment.

FIG. 36 is a diagram showing one step of the method for designing a phase modulation layer according to the present embodiment.

FIG. 37 is a diagram for explaining step S104 shown in FIG. 36.

FIG. 38 is a diagram showing one step of a method for designing a phase modulation layer according to the present embodiment.

FIG. 39 is a diagram showing one step of a method for manufacturing a semiconductor light emitting element according to the present embodiment.

FIG. 40 is a diagram showing one step of a method for manufacturing a semiconductor light emitting element according to the present embodiment.

FIG. 41 is a diagram showing one step of a method for manufacturing a semiconductor light emitting element according to the present embodiment.

FIG. 42 is a diagram showing one step of a method for manufacturing a semiconductor light emitting element according to the present embodiment.

FIG. 43 is a diagram for explaining the effects of the design method according to the present embodiment.

FIG. 44 is a diagram for explaining the effects of the design method according to the present embodiment.

FIG. 45 is a diagram for explaining a modification example of the method for designing a phase modulation layer.

### DESCRIPTION OF EMBODIMENTS

Hereinafter, an embodiment of a light emitting element will be described in detail with reference to the accompanying diagrams. In addition, in the description of the diagrams, the same elements are denoted by the same reference numerals, and the repeated description thereof will be omitted.

### One Embodiment of Light Emitting Element

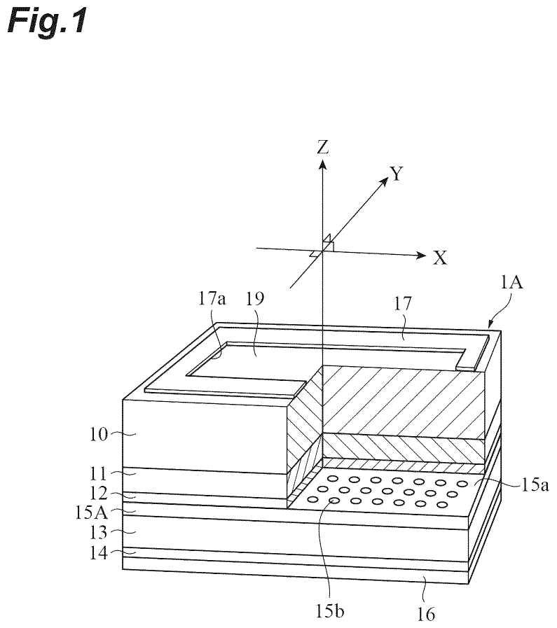

FIG. 1 is a perspective view showing the configuration of a semiconductor light emitting element 1A according to an embodiment.

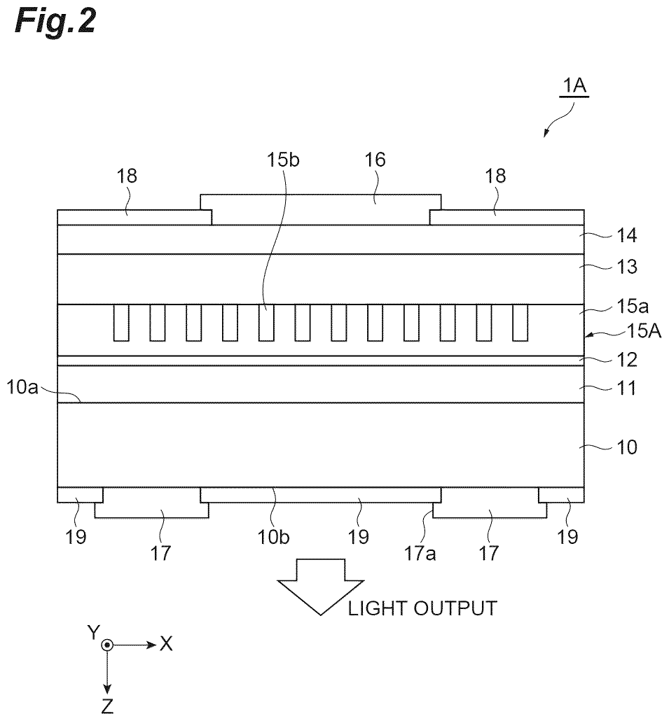

FIG. 2 is a cross-sectional view showing the stacked structure of the semiconductor light emitting element 1A. In addition, an XYZ Cartesian coordinate system is defined in which the Z axis is an axis passing through the center of the semiconductor light emitting element 1A and extending in the thickness direction of the semiconductor light emitting element 1A. The semiconductor light emitting element (light emitting element) 1A is an S-iPMSEL that forms a standing wave in a direction in the XY plane and outputs a phase-controlled plane wave in the Z-axis direction. As will be described later, the semiconductor light emitting element 1A outputs an optical image in any two-dimensional shape including a direction perpendicular to a main surface 10a of a semiconductor substrate 10 (that is, the Z-axis direction), a direction inclined with respect to the direction perpendicular to the main surface 10a, or both.

As shown in FIGS. 1 and 2, the semiconductor light emitting element 1A includes an active layer 12 as a light emitting portion provided on the semiconductor substrate 10, a pair of cladding layers 11 and 13 between which the active layer 12 is interposed, and a contact layer 14 provided on the cladding layer 13. The semiconductor substrate 10 and the layers 11 to 14 are formed of, for example, compound semiconductor such as GaAs-based semiconductor, InP-based semiconductor, or nitride-based semiconductor. The energy bandgap of the cladding layer 11 and the energy bandgap of the cladding layer 13 are larger than the energy bandgap of the active layer 12. The thickness directions of the semiconductor substrate 10 and the layers 11 to 14 match the Z-axis direction.

The semiconductor light emitting element 1A further includes a phase modulation layer 15A optically coupled to the active layer 12. In the present embodiment, the phase modulation layer 15A is provided between the active layer 12 and the cladding layer 13. If necessary, a light guide layer may be provided at least between the active layer 12 and the cladding layer 13 or between the active layer 12 and the cladding layer 11. The thickness direction of the phase modulation layer 15A matches the Z-axis direction. In addition, the optical guide layer may include a carrier barrier layer for efficiently confining carriers in the active layer 12.

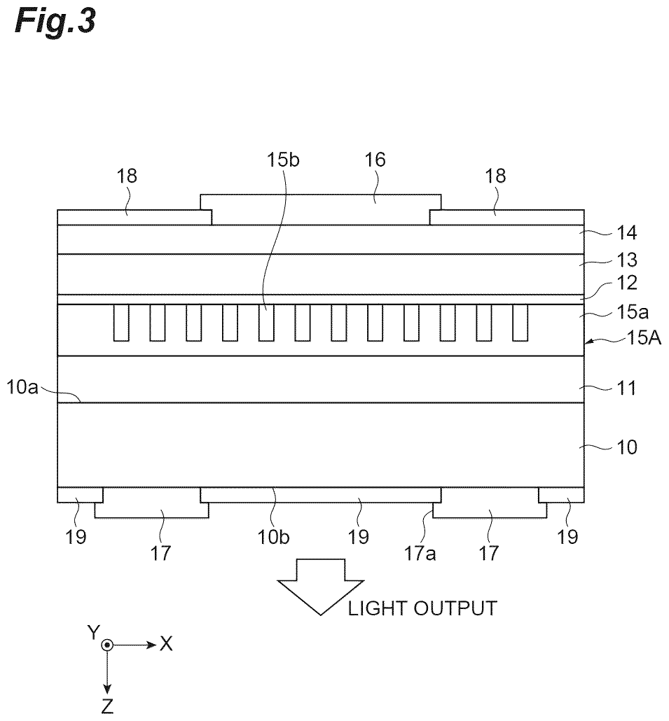

As shown in FIG. 3, the phase modulation layer 15A may be provided between the cladding layer 11 and the active layer 12.

The phase modulation layer 15A includes a base layer 15a formed of a first refractive index medium and a plurality of different refractive index regions 15b formed of a second refractive index medium having a different refractive index from the first refractive index medium and present in the base layer 15a. The plurality of different refractive index regions 15b include a substantially periodic structure. Assuming that the equivalent refractive index of the mode is n, the wavelength λ0 (=(√2)a×n, a is the lattice spacing) selected by the phase modulation layer 15A is included within the emission wavelength range of the active layer 12. The phase modulation layer 15A can select a band edge wavelength near the wavelength λ0 among the emission wavelengths of the active layer 12 and output this to the outside. The laser light entering the phase modulation layer 15A forms a predetermined mode according to the arrangement of the different refractive index regions 15b within the phase modulation layer 15A, and is emitted to the outside from the surface of the semiconductor light emitting element 1A as a laser beam having a desired pattern (optical image).

The semiconductor light emitting element 1A further includes an electrode 16 provided on the contact layer 14 and an electrode 17 provided on a back surface 10b of the semiconductor substrate 10. The electrode 16 is in ohmic contact with the contact layer 14, and the electrode 17 is in ohmic contact with the semiconductor substrate 10. In addition, the electrode 17 has an opening 17a. The electrode 16 is provided in the central region of the contact layer 14. A portion other than the electrode 16 on the contact layer 14 is covered with a protective film 18 (see FIG. 2). In addition, the contact layer 14 that is not in contact with the electrode 16 may be removed. A portion (including the inside of the opening 17a) of the back surface 10b of the semiconductor substrate 10 other than the electrode 17 is covered with an antireflection film 19. The antireflection film 19 located in a region other than the opening 17a may be removed.

When a driving current is supplied between the electrodes 16 and 17, electrons and holes recombine within the active layer 12 and accordingly, the active layer 12 emits light. Electrons and holes contributing to this light emission and the generated light are efficiently confined between the cladding layer 11 and the cladding layer 13.

The light emitted from the active layer 12 enters the phase modulation layer 15A to form a predetermined mode according to the lattice structure inside the phase modulation layer 15A. The laser light emitted from the phase modulation layer 15A is directly output from the back surface 10b to the outside of the semiconductor light emitting element 1A through the opening 17a, or is output from the back surface 10b to the outside of the semiconductor light emitting element 1A through the opening 17a after being reflected at the electrode 16. At this time, signal light included in the laser light is emitted in any two-dimensional directions including a direction perpendicular to the main surface 10a and a direction inclined with respect to the direction perpendicular to the main surface 10a. The signal light forms a desired optical image. The signal light is mainly 1st-order light and −1st-order light. As described above, no 0th-order light is output from the phase modulation layer 15A of the present embodiment.

In an example, the semiconductor substrate 10 is a GaAs substrate, and the cladding layer 11, the active layer 12, the cladding layer 13, the contact layer 14, and the phase modulation layer 15A are compound semiconductor layers formed of a group III element and a group V element. In one practical example, the cladding layer 11 is an AlGaAs layer, the active layer 12 has a multiple quantum well structure (barrier layer: AlGaAs/well layer: InGaAs), the base layer 15a of the phase modulation layer 15A is GaAs, the different refractive index region 15b is a vacancy, the cladding layer 13 is an AlGaAs layer, and the contact layer 14 is a GaAs layer.

In the above case, the thickness of the semiconductor substrate 10 is 50 to 300 (μm), and is 150 μm in one practical example. The semiconductor substrate may be thicker than this if it is possible to separate the elements, and conversely, the semiconductor substrate is not necessarily required in the case of a structure having a separate support substrate. The thickness of the cladding layer 11 is 500 to 10000 (nm), and is 2000 (nm) in one practical example. The thickness of the active layer 12 is 100 to 300 (nm), and is 175 (nm) in one practical example. The thickness of the phase modulation layer 15A is 100 to 500 (nm), and is 280 (nm) in one practical example. The thickness of the cladding layer 13 is 500 to 10000 (nm), and is 2000 (nm) in one practical example. The thickness of contact layer 14 is 50 to 500 (nm), and is 150 (nm) in one practical example.

In AlGaAs, the energy bandgap and refractive index can be easily changed by changing the composition ratio of Al. In AlxGa1-xAs, when the composition ratio x of Al having a relatively small atomic radius decreases (increases), the energy bandgap that is positively correlated with this decreases (increases), and when GaAs is mixed with In having a large atomic radius to obtain InGaAs, the energy band gap decreases. That is, the Al composition ratio of the cladding layers 11 and 13 is larger than the Al composition ratio of the barrier layer (AlGaAs) of the active layer 12. The Al composition ratio of the cladding layers 11 and 13 is set to, for example, 0.2 to 1.0, and is 0.4 in one practical example. The Al composition ratio of the barrier layer of the active layer 12 is set to, for example, 0 to 0.3, and 0.15 in one practical example.

In another example, the semiconductor substrate 10 is an InP substrate, and the cladding layer 11, the active layer 12, the phase modulation layer 15A, the cladding layer 13, and the contact layer 14 are formed of, for example, InP-based compound semiconductor. In one practical example, the cladding layer 11 is an InP layer, the active layer 12 has a multiple quantum well structure (barrier layer: GaInAsP/well layer: GaInAsP), the base layer 15a of the phase modulation layer 15A is GaInAsP or InP, the different refractive index region 15b is a vacancy, the cladding layer 13 is an InP layer, and the contact layer 14 is GaInAsP, GaInAs, or InP.

In still another example, the semiconductor substrate 10 is an InP substrate, and the cladding layer 11, the active layer 12, the phase modulation layer 15A, the cladding layer 13, and the contact layer 14 are formed of, for example, InP-based compound semiconductor. In one practical example, the cladding layer 11 is an InP layer, the active layer 12 has a multiple quantum well structure (barrier layer: AlGaInAs/well layer: AlGaInAs), the base layer 15a of the phase modulation layer 15A is AlGaInAs or InP, the different refractive index region 15b is a vacancy, the cladding layer 13 is an InP layer, and the contact layer 14 is a GaInAs or InP layer. In this material system or the material system using GaInAsP/InP described in the previous paragraph, applications to optical communication wavelengths in the 1.3/1.55 μm band are possible, and it is possible to emit light with an eye-safe wavelength longer than 1.4 μm.

In still another example, the semiconductor substrate 10 is a GaN substrate, the cladding layer 11, the active layer 12, the phase modulation layer 15A, the cladding layer 13, and the contact layer 14 are formed of, for example, nitride-based compound semiconductor. In one practical example, the cladding layer 11 is an AlGaN layer, the active layer 12 has a multiple quantum well structure (barrier layer: InGaN/well layer: InGaN), the base layer 15a of the phase modulation layer 15A is GaN, the different refractive index region 15b is a vacancy, the cladding layer 13 is an AlGaN layer, and the contact layer 14 is a GaN layer.

The cladding layer 11 has the same conductivity type as the semiconductor substrate 10, and the cladding layer 13 and the contact layer 14 have a conductivity type opposite to that of the semiconductor substrate 10. In one example, the semiconductor substrate 10 and the cladding layer 11 are n-type, and the cladding layer 13 and the contact layer 14 are p-type. The phase modulation layer 15A has the same conductivity type as the semiconductor substrate 10 when the phase modulation layer 15A is provided between the active layer 12 and the cladding layer 11, and has a conductivity type opposite to that of the semiconductor substrate 10 when the phase modulation layer 15A is provided between the active layer 12 and the cladding layer 13. In addition, the impurity concentration is, for example, 1×10¹⁶ to 1×10²¹/cm³. The active layer 12 is intrinsic (i-type) to which no impurity is intentionally added, and its impurity concentration is 1×10¹⁶/cm³ or less. In addition, the impurity concentration of the phase modulation layer 15A may be intrinsic (i-type) when it is necessary to suppress the influence of loss due to light absorption through impurity levels.

In the above structure, the different refractive index region 15b is a vacancy. However, the different refractive index region 15b may be formed by filling a vacancy with a semiconductor having a different refractive index from that of the base layer 15a. In this case, for example, a vacancy in the base layer 15a may be formed by etching, and a semiconductor may be filled in the vacancy by using a metal organic chemical vapor deposition, a sputtering method, or an epitaxial method. For example, when the base layer 15a is formed of GaAs, the different refractive index region 15b may be formed of AlGaAs. In addition, after forming the different refractive index region 15b by filling the vacancy in the base layer 15a with a semiconductor, the same semiconductor as the different refractive index region 15b may be further deposited thereon. In addition, when the different refractive index region 15b is a vacancy, the vacancy may be filled with an inert gas, such as argon or nitrogen, or a gas such as hydrogen or air.

The antireflection film 19 is formed of a dielectric single-layer film or a dielectric multilayer film of silicon nitride (for example, SiN) or silicon oxide (for example, SiO₂), for example. As the dielectric multilayer film, for example, it is possible to use a film in which two or more types of dielectric layers selected from a dielectric layer group of titanium oxide (TiO₂), silicon dioxide (SiO₂), silicon monoxide (SiO), niobium oxide (Nb₂O₅), tantalum pentoxide (Ta₂O₅), magnesium fluoride (MgF₂), titanium oxide (TiO₂), aluminum oxide (Al₂O₃), cerium oxide (CeO₂), indium oxide (In₂O₃), zirconium oxide (ZrO₂), and the like are stacked. For example, a film having a thickness of λ/4, which is an optical film thickness for light having a wavelength λ, is stacked. In addition, the protective film 18 is an insulating film formed of silicon nitride (for example, SiN) or silicon oxide (for example, SiO₂), for example. When the semiconductor substrate 10 and the contact layer 14 are formed of GaAs-based semiconductor, the electrode 16 can be formed of a material containing Au and at least one of Cr, Ti, and Pt. For example, the electrode 16 has a stacked structure of a Cr layer and an Au layer. The electrode 17 can be formed of a material containing Au and at least one of AuGe and Ni. For example, the electrode 17 has a stacked structure of an AuGe layer and an Au layer. In addition, the materials for the electrodes 16 and 17 are not limited to these ranges as long as it is possible to achieve ohmic contact.

In addition, it is also possible to emit laser light from the surface of the contact layer 14 by changing the shape of the electrode. That is, when the opening 17a of the electrode 17 is not provided and the electrode 16 is opened on the surface of the contact layer 14, a light beam is emitted from the surface of the contact layer 14 to the outside. In this case, the antireflection film is provided in and around the opening of the electrode 16.

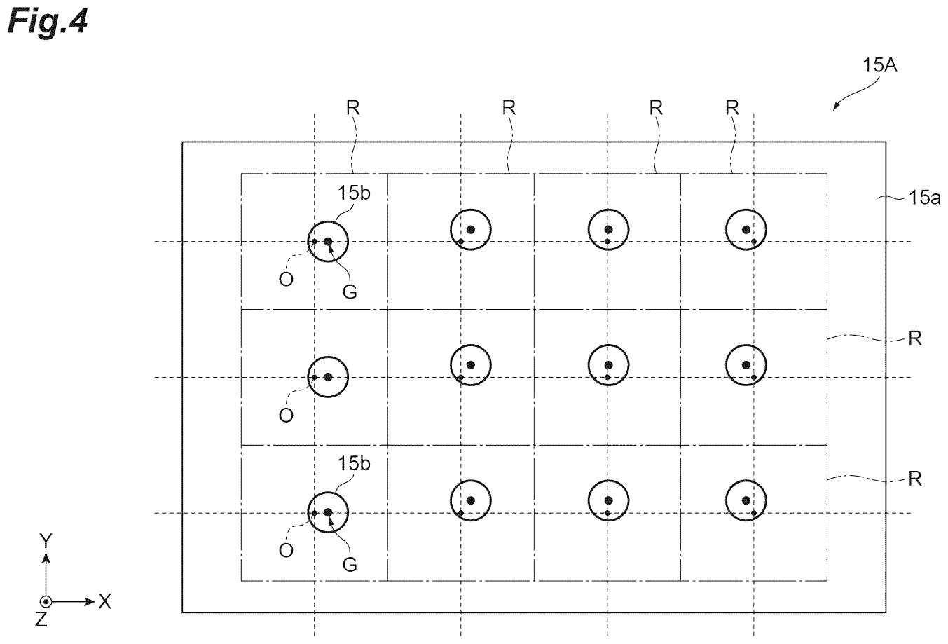

FIG. 4 is a plan view of the phase modulation layer 15A. The phase modulation layer 15A includes the base layer 15a formed of a first refractive index medium and a plurality of different refractive index regions 15b formed of a second refractive index medium having a different refractive index from the first refractive index medium. Here, a virtual square lattice in the XY plane is set in the phase modulation layer 15A. It is assumed that one side of the square lattice is parallel to the X axis and the other side is parallel to the Y axis. At this time, a square-shaped unit constituent region R centered on a lattice point O of the square lattice can be set two-dimensionally over a plurality of columns along the X axis and a plurality of rows along the Y axis. Assuming that the XY coordinates of each unit constituent region R are given by the center of gravity position of each unit constituent region R, this center of gravity position matches the lattice point O of the virtual square lattice. The plurality of different refractive index regions 15b are provided, for example, one by one in each unit constituent region R. The planar shape of the different refractive index region 15b is, for example, circular. The lattice point O may be located outside the different refractive index region 15b, or may be included in the different refractive index region 15b.

The ratio of the area S of the different refractive index region 15b within one unit constituent region R is referred to as a filling factor (FF). Assuming that the lattice spacing of the square lattice is a, the filling factor FF of the different refractive index region 15b is given as S/a². S is the area of the different refractive index region 15b in the XY plane. For example, when the different refractive index region 15b has a perfect circular shape, S=π(d/2)² is given by using the diameter d of a perfect circle. In addition, when the shape of the different refractive index region 15b is a square, S=LA² is given by using the length LA of one side of the square.

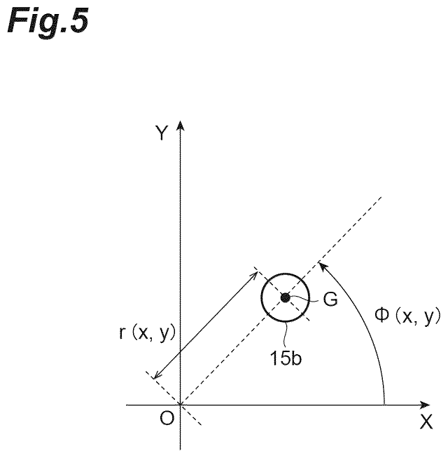

FIG. 5 is an enlarged view of a part (unit constituent region R) of the phase modulation layer 15A. As shown in FIG. 5, each of the different refractive index regions 15b has a center of gravity G. Here, the angle formed by the vector from the lattice point O toward the center of gravity G and the X axis is assumed to be ϕ(x, y). x indicates the position of the x-th lattice point on the X axis, and y indicates the position of the y-th lattice point on the Y axis. When the rotation angle ϕ is 0°, the direction of the vector connecting the lattice point O and the center of gravity G to each other matches the positive direction of the X axis. In addition, the length of the vector connecting the lattice point O and the center of gravity G to each other is assumed to be r(x, y). In one example, r(x, y) is constant (over the entire phase modulation layer 15A) regardless of x or y.

As shown in FIG. 4, the direction of the vector connecting the lattice point O and the center of gravity G to each other, that is, the rotation angle ϕ of the center of gravity G of the different refractive index region 15b around the lattice point O is set individually for each lattice point O according to the phase pattern corresponding to the desired optical image. The phase pattern, that is, the rotation angle distribution ϕ(x, y) has a specific value for each position determined by the values of x and y, but is not necessarily expressed by a specific function. That is, the rotation angle distribution ϕ(x, y) is determined from the phase distribution extracted from the complex amplitude distribution obtained by Fourier transform of the desired optical image. In addition, when calculating the complex amplitude distribution from the desired optical image, the reproducibility of the beam pattern is improved by applying an iterative algorithm such as a Gerchberg-Saxton (GS) method, which is generally used in calculations for hologram generation.

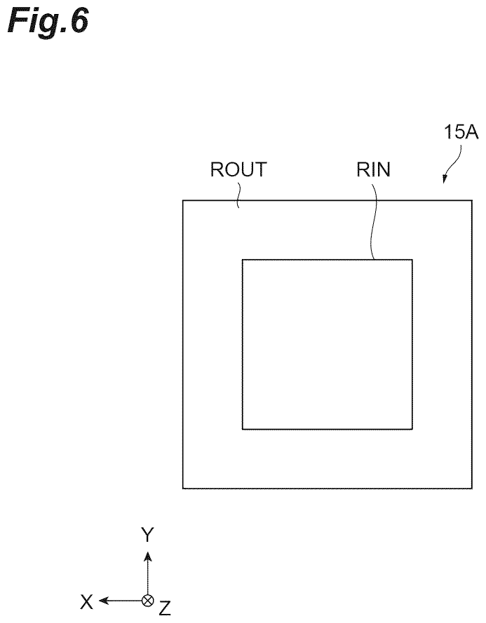

FIG. 6 is a plan view showing an example in which the substantially periodic refractive index structure in FIG. 4 is applied only within a specific region of the phase modulation layer. In the example shown in FIG. 6, a substantially periodic structure (for example, the structure shown in FIG. 4) for emitting a target beam pattern is formed inside a square-shaped inner region RIN. On the other hand, in an outer region ROUT surrounding the inner region RIN, a perfectly circular different refractive index region with the same center of gravity is arranged at the lattice point position of the square lattice. For example, the filling factor FF in the outer region ROUT is set to 12%. In addition, the lattice spacing of the virtually set square lattice is the same (=a) both inside the inner region RIN and inside the outer region ROUT. The advantage of this structure is that the generation of high-frequency noise (so-called window function noise) caused by sudden changes in light intensity in the periphery of the inner region RIN can be suppressed because light is also distributed within the outer region ROUT. In addition, since light leakage in the in-plane direction can be suppressed, a reduction in threshold current can be expected.

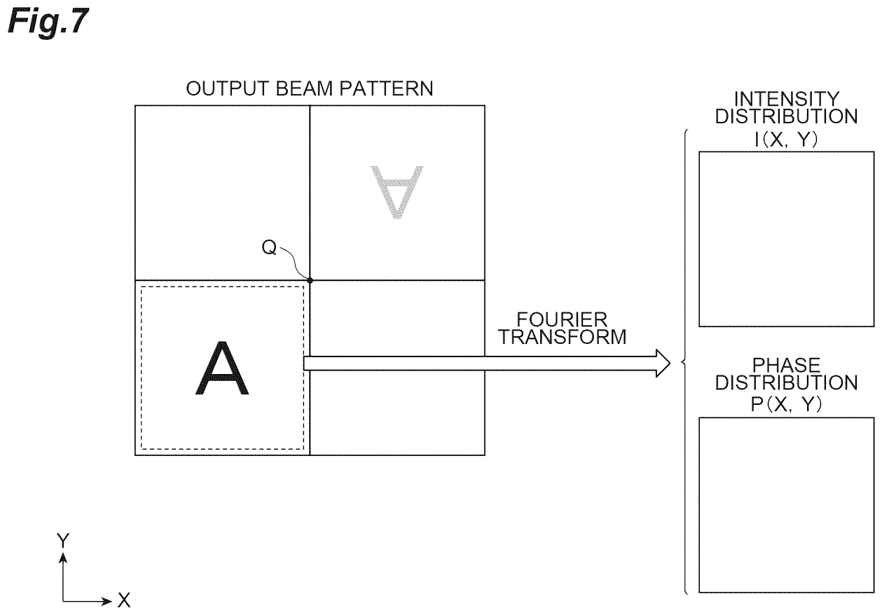

FIG. 7 is a diagram for explaining the relationship between an optical image obtained by imaging the output beam pattern of the semiconductor light emitting element 1A and the rotation angle distribution ϕ(x, y) in the phase modulation layer 15A. In addition, the center Q of the output beam pattern is not necessarily located on the axis perpendicular to the main surface 10a of the semiconductor substrate 10, but can be located on the perpendicular axis. For the sake of explanation, it is assumed herein that the center Q is on the axis perpendicular to the main surface 10a. FIG. 7 shows four quadrants with the center Q as their origin. FIG. 7 shows a case where optical images are obtained in the first and third quadrants as an example, but it is also possible to obtain images in the second and fourth quadrants or in all quadrants. In the present embodiment, as shown in FIG. 7, optical images that are point-symmetrical with respect to the origin are obtained. FIG. 7 shows, as an example, a case where the letter “A” is obtained in the third quadrant and a pattern obtained by rotating the letter “A” by 180 degrees is obtained in the first quadrant. In addition, in the case of rotationally symmetrical optical images (for example, a cross, a circle, or a double circle), the rotationally symmetrical optical images overlap each other and are observed as one optical image.

The optical image of the output beam pattern of the semiconductor light emitting element 1A includes at least one of a spot, a straight line, a cross, a line drawing, a lattice pattern, a photograph, a striped pattern, CG (computer graphics), and letters. Here, in order to obtain a desired optical image, the rotation angle distribution ϕ(x, y) of the different refractive index region 15b of the phase modulation layer 15A is determined by the following procedure.

In the present embodiment, a desired optical image can be obtained by determining the rotation angle distribution ϕ(x, y) according to the following procedure. First, as a first prerequisite, in the XYZ Cartesian coordinate system defined by a Z axis that matches the normal direction and an XY plane that includes an X axis and a Y axis perpendicular to each other and matches one surface of the phase modulation layer 15A including a plurality of different refractive index regions 15b, a virtual square lattice formed by M1 (an integer of 1 or more)×N1 (an integer of 1 or more) unit constituent regions R, each of which has a square shape, is set on the XY plane.

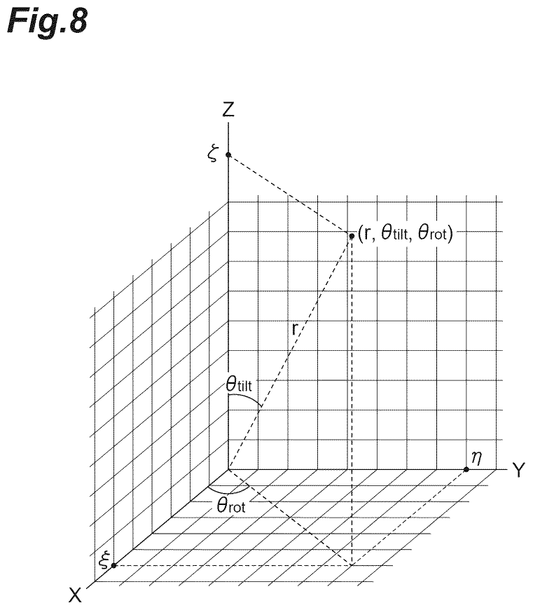

As a second prerequisite, it is assumed that the coordinates (ξ, η, ζ) in the XYZ Cartesian coordinate system satisfy the relationship shown in the following Equations (1) to (3) with respect to the spherical coordinates (r, θᵣₒₜ, θₜᵢₗₜ) defined by the length r of the radius, a tilt angle θₜᵢₗₜ from the Z axis, and a rotation angle θᵣₒₜ from the X axis specified on the X-Y plane, as shown in FIG. 8. In addition, FIG. 8 is a diagram for explaining coordinate transformation from the spherical coordinates (r, θᵣₒₜ, θₜᵢₗₜ) to the coordinates (ξ, η, ζ) in the XYZ Cartesian coordinate system. By the coordinates (ξ, η, ζ), a designed optical image on a predetermined plane set in the XYZ Cartesian coordinate system, which is the real space, is expressed. Assuming that the beam pattern corresponding to the optical image output from the semiconductor light emitting element is a group of bright spots directed in a direction defined by the angles θₜᵢₗₜ and θᵣₒₜ, it is assumed that the angles θₜᵢₗₜ and θᵣₒₜ are converted into a coordinate value kₓ on the Kx axis, which is a normalized wave number defined by the following Equation (4) and corresponds to the X axis, and a coordinate value k_{y} on the Ky axis, which is a normalized wave number defined by the following Equation (5), corresponds to the Y axis, and is perpendicular to the Kx axis. The normalized wave number means a wave number normalized by setting the wave number 2π/a corresponding to the lattice spacing of the virtual square lattice to 1.0. At this time, in the wave number space defined by the Kx axis and the Ky axis, a specific wave number range including a beam pattern corresponding to an optical image is M2 (an integer of 1 or more)×N2 (an integer of 1 or more) image regions FR each having a square shape. In addition, the integer M2 does not need to match the integer M1. Similarly, the integer N2 does not need to match the integer N1. In addition, Equations (4) and (5) are disclosed, for example, in Y. Kurosaka et al., “Effects of non-lasing band in two-dimensional photonic-crystal lasers clarified using omnidirectional band structure”, opt. Express 20, 21773-21783 (2012).

$$\begin{matrix}[ Equation 1 ] & \\ ξ = r sin {θ}_{tilt} cos {θ}_{rot} & ( 1 )\end{matrix}$$

$$\begin{matrix}[ Equation 2 ] & \\ η = r sin {θ}_{tilt} sin {θ}_{rot} & ( 2 )\end{matrix}$$

$$\begin{matrix}[ Equation 3 ] & \\ ζ = r cos {θ}_{tilt} & ( 3 )\end{matrix}$$

$$\begin{matrix}[ Equation 4 ] & \\ {k}_{x} = \frac{a}{λ} sin {θ}_{tilt} cos {θ}_{r o t} & ( 4 )\end{matrix}$$

$$\begin{matrix}[ Equation 5 ] & \\ {k}_{y} = \frac{a}{λ} sin {θ}_{tilt} sin {θ}_{rot} & ( 5 )\end{matrix}$$

a: lattice constant of virtual square lattice
λ: oscillation wavelength of semiconductor light emitting element 1A.

As a third prerequisite, in the wave number space, a complex amplitude F(x, y) obtained by performing a two-dimensional inverse discrete Fourier transform of each image region FR (kₓ, k_{y}), which is specified by a coordinate component kₓ (an integer of 0 to M2-1) in the Kx-axis direction and a coordinate component k_{y} (an integer of 0 to N2-1) in the Ky-axis direction, into a unit constituent region R(x, y) on the XY plane, which is specified by a coordinate component x (an integer of 0 to M1-1) in the X-axis direction and a coordinate component y (an integer of 0 to N1-1) in the Y-axis direction, is given by the following Equation (6) with j as an imaginary unit. In addition, the complex amplitude F(x, y) is defined by the following Equation (7) when the amplitude term is A(x, y) and the phase term is P(x, y). In addition, as a fourth prerequisite, the unit constituent region R(x, y) is defined by an s axis and a t axis, which are parallel to the X axis and the Y axis, respectively, and are perpendicular to each other at the lattice point O(x, y) that is the center of the unit constituent region R(x, y).

$$\begin{matrix}[ Equation 6 ] & \\ F ( x , y ) = {\sum }_{{k}_{x} = 0}^{M 2 - 1} {\sum }_{{k}_{y} = 0}^{N 2 - 1} F R ( {k}_{x} , {k}_{y} ) exp [ j 2 π ( \frac{{k}_{x}}{M 2} x + \frac{{k}_{y}}{N 2} y ) ] & ( 6 )\end{matrix}$$

$$\begin{matrix}[ Equation 7 ] & \\ F ( x , y ) = A ( x , y ) \times exp [ j P ( x , y ) ] & ( 7 )\end{matrix}$$

Under the first to fourth prerequisites described above, the phase modulation layer 15A is formed so as to satisfy the following first and second conditions. That is, the first condition is that the center of gravity G is located away from the lattice point O(x, y) within the unit constituent region R(x, y). In addition, the second condition is that the corresponding different refractive index region 15b is arranged within the unit constituent region R(x, y) so that the angle ϕ(x, y) formed by the s axis and the line segment connecting the lattice point O(x, y) and the corresponding center of gravity G to each other satisfies the following relationship in a state in which a line segment length r₂(x, y) from the lattice point O(x, y) to the corresponding center of gravity G is set to a common value in the M1× N1 unit constituent regions.

$$ϕ ( x , y ) = C \times P ( x , y ) + B$$

C: constant of proportionality, for example, 180°/π
B: any constant, for example, 0

As a method to obtain the intensity distribution and the phase distribution from the complex amplitude distribution obtained by Fourier transform, for example, an intensity distribution I(x, y) can be calculated by using the abs function of MathWorks' numerical analysis software “MATLAB (registered trademark)”, and a phase distribution P(x, y) can be calculated by using the MATLAB's angle function.

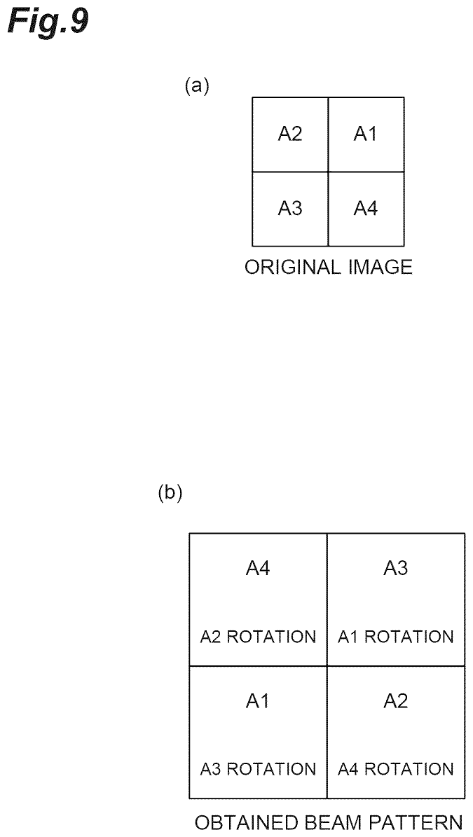

Here, points to be noted will be described in the case of calculation using general discrete Fourier transform (or fast Fourier transform) when calculating the rotation angle distribution ϕ(x, y) from the Fourier transform result of the optical image and determining the arrangement of each different refractive index region 15b. If the optical image before the Fourier transform is divided into four quadrants, A1, A2, A3, and A4 as shown in FIG. 9(a), the resulting beam pattern is shown in FIG. 9(b). That is, in the first quadrant of the beam pattern, a pattern appears in which that obtained by rotating the first quadrant in FIG. 9(a) by 180 degrees and the third quadrant in FIG. 9(a) are superimposed. In the second quadrant of the beam pattern, a pattern appears in which that obtained by rotating the second quadrant in FIG. 9(a) by 180 degrees and the fourth quadrant in FIG. 9(a) are superimposed. In the third quadrant of the beam pattern, a pattern appears in which that obtained by rotating the third quadrant in FIG. 9(a) by 180 degrees and the first quadrant in FIG. 9(a) are superimposed. In the fourth quadrant of the beam pattern, a pattern appears in which that obtained by rotating the fourth quadrant in FIG. 9(a) by 180 degrees and the second quadrant in FIG. 9(a) are superimposed.

Therefore, when an optical image (original optical image) before the Fourier transform that has a value only in the first quadrant is used, the first quadrant of the original optical image appears in the third quadrant of the resulting beam pattern, and a pattern obtained by rotating the first quadrant of the original optical image by 180 degrees appears in the first quadrant of the resulting beam pattern.

Thus, in the semiconductor light emitting element 1A, a desired beam pattern is obtained by the phase modulation of the wavefront. This beam pattern is not only a pair of single peak beams (spots), but also can be a character shape, a group of two or more spots having the same shape, or a vector beam whose phase and intensity distribution are spatially non-uniform.

In addition, the refractive index of the base layer 15a can be 3.0 to 3.5, and the refractive index of the different refractive index region 15b can be 1.0 to 3.4. In addition, the average radius of each different refractive index region 15b in the hole of the base layer 15a is, for example, 20 nm to 90 nm in the case of 940 nm band. The diffraction intensity changes as the size of each different refractive index region 15b changes. This diffraction efficiency is proportional to the optical coupling coefficient expressed by the coefficient when the shape of the different refractive index region 15b is Fourier-transformed. The optical coupling coefficient is described in, for example, Y Liang et al., “Three-dimensional coupled-wave analysis for square-lattice photonic crystal surface emitting lasers with transverse-electric polarization: finite-size effects”, Optics Express 20, 15945 to 15961 (2012).

Next, the characteristics of the phase modulation layer 15A of the present embodiment will be described in detail. In the present embodiment, the lattice spacing a of the virtual square lattice and the emission wavelength λ of the active layer 12 satisfy the conditions for M-point oscillation. In addition, when considering the reciprocal lattice space in the phase modulation layer 15A, in-plane wave number vectors in four directions that form standing waves each including a wave number spread corresponding to the angular spread of the optical image are formed due to phase modulation according to the rotation angle distribution ϕ(x, y). Then, the magnitude of at least one of the in-plane wave number vectors is smaller than 2π/λ(light line). These points will be described in detail below.

First, for comparison, a photonic crystal laser (PCSEL) that oscillates at τ point will be described. The PCSEL is a semiconductor element that has an active layer and a photonic crystal layer in which a plurality of different refractive index regions are arranged periodically in a two-dimensional manner and that outputs laser light in a direction perpendicular to the main surface of a semiconductor substrate while forming a standing wave with an oscillation wavelength corresponding to the arrangement period of different refractive index regions in a plane perpendicular to the thickness direction of the photonic crystal layer. In addition, for τ-point oscillation, it is preferable that the lattice spacing a of the virtual square lattice, the emission wavelength λ of the active layer 12, and the equivalent refractive index n of the mode satisfy the conditions of λ=na.

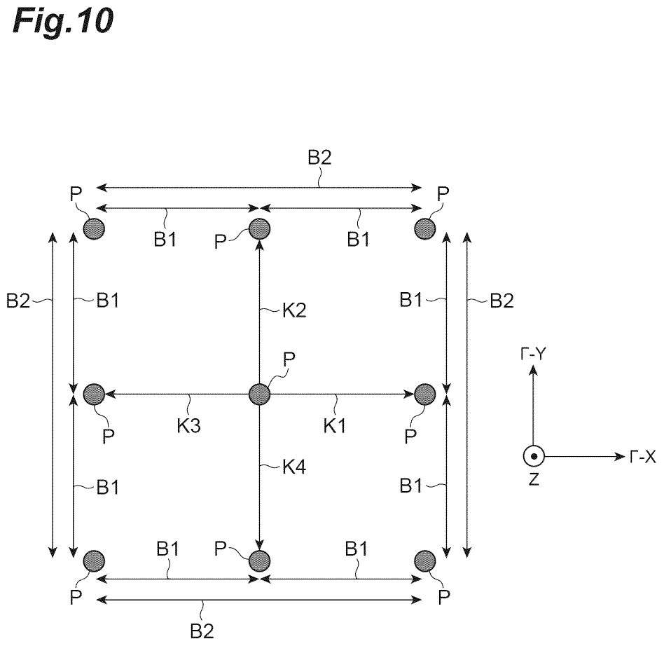

FIG. 10 is a plan view showing a reciprocal lattice space regarding a photonic crystal layer of a PCSEL that oscillates at the F point. This diagram shows a case where a plurality of different refractive index regions are located on the lattice points of a square lattice, and a point P in the diagram indicates a reciprocal lattice point. In addition, an arrow B1 in the diagram indicates a fundamental reciprocal lattice vector, and an arrow B2 indicates a reciprocal vector twice the fundamental reciprocal lattice vector BL. In addition, arrows K1, K2, K3, and K4 indicate four in-plane wave number vectors. The four in-plane wave number vectors K1, K2, K3, and K4 are combined with each other through 90° and 180° diffraction to form a standing wave state. Here, a τ-X axis and a τ-Y axis perpendicular to each other in the reciprocal lattice space are defined. The τ-X axis is parallel to one side of the square lattice, and the τ-Y axis is parallel to the other side of the square lattice. The in-plane wave number vector is a vector obtained by projecting the wave number vector onto the τ-X·τ-Y plane. That is, the in-plane wave number vector K1 points in the positive direction of the τ-X axis, the in-plane wave number vector K2 points in the positive direction of the τ-Y axis, the in-plane wave number vector K3 points in the negative direction of the τ-X axis, and the in-plane wave number vector K4 points in the negative direction of the τ-Y axis. As is apparent from FIG. 10, in the PCSEL that oscillates at the τ point, the magnitudes of the in-plane wave number vectors K1 to K4 (that is, the magnitude of the standing wave in the in-plane direction) are equal to the magnitude of the fundamental reciprocal lattice vector B1. In addition, assuming that the magnitudes of the in-plane wave number vectors K1 to K4 are k, the following Equation (8) is obtained.

$$\begin{matrix}[ Equation 8 ] & \\ k = \vert B 1 \vert = \frac{2 π}{a} & ( 8 )\end{matrix}$$

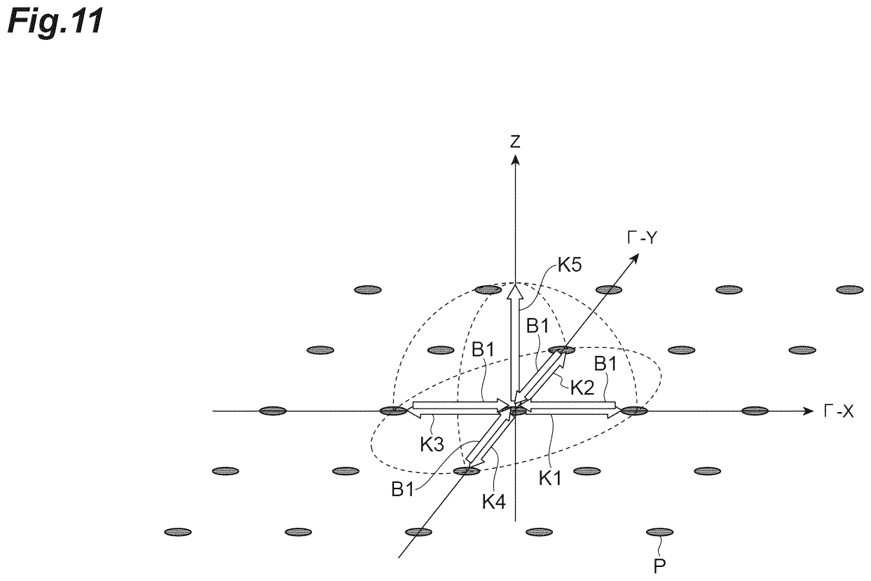

FIG. 11 is a three-dimensional perspective view of the reciprocal lattice space shown in FIG. 10. FIG. 11 shows a Z axis perpendicular to the directions of the τ-X axis and the τ-Y axis. This Z axis is the same as the Z axis shown in FIG. 1. As shown in FIG. 11, in the case of the PCSEL that oscillates at the τ point, the wave number in the in-plane direction becomes 0 due to diffraction, and diffraction occurs in a direction perpendicular to the plane (Z-axis direction) (arrow K5 in the diagram). Therefore, the laser light is basically output in the Z-axis direction.

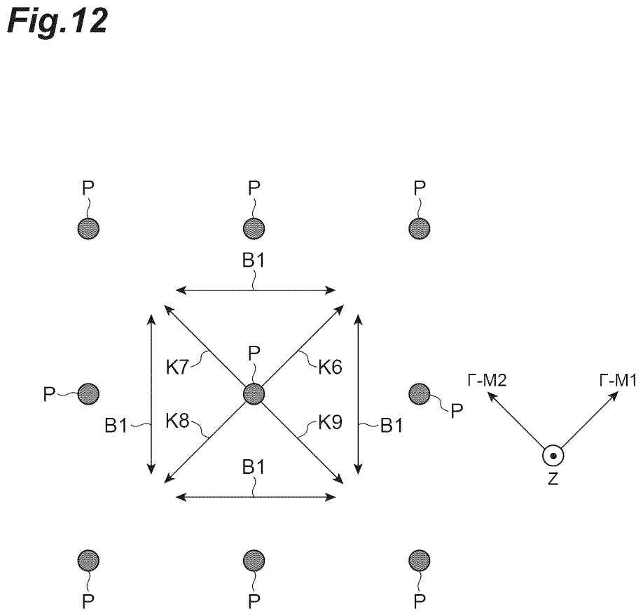

Next, a PCSEL that oscillates at M point will be described. For M-point oscillation, it is preferable that the lattice spacing a of the virtual square lattice, the emission wavelength λ of the active layer 12, and the equivalent refractive index n of the mode satisfy the conditions of λ=(√2)n×a. FIG. 12 is a plan view showing a reciprocal lattice space regarding a photonic crystal layer of a PCSEL that oscillates at the M point. This diagram also shows a case where a plurality of different refractive index regions are located on lattice points of a square lattice, and the point P in the diagram indicates a reciprocal lattice point. In addition, an arrow B1 in the diagram indicates a fundamental reciprocal lattice vector similar to that in FIG. 10, and arrows K6, K7, K8, and K9 indicate four in-plane wave number vectors. Here, a τ-M1 axis and a τ-M2 axis perpendicular to each other in the reciprocal lattice space are defined. The τ-M1 axis is parallel to one diagonal direction of the square lattice, and the τ-M2 axis is parallel to the other diagonal direction of the square lattice. The in-plane wave number vector is a vector obtained by projecting the wave number vector onto the τ-M1·τ-M2 plane. That is, the in-plane wave number vector K6 points in the positive direction of the τ-M1 axis, the in-plane wave number vector K7 points in the positive direction of the τ-M2 axis, the in-plane wave number vector K8 points in the negative direction of the τ-M1 axis, and the in-plane wave number vector K9 points in the negative direction of the τ-M2 axis. As is apparent from FIG. 12, in the PCSEL that oscillates at the M point, the magnitudes of the in-plane wave number vectors K6 to K9 (that is, the magnitude of the standing wave in the in-plane direction) are smaller than the magnitude of the fundamental reciprocal lattice vector B1. In addition, assuming that the magnitudes of the in-plane wave number vectors K6 to K9 are k, the following Equation (9) is obtained.

$$\begin{matrix}[ Equation 9 ] & \\ k = \frac{1}{\sqrt{2}} \frac{2 π}{a} & ( 9 )\end{matrix}$$

Diffraction occurs in the direction of the vector sum of a reciprocal lattice vector G (=2 mπ/a, m: integer) for the wave number vectors K6 to K9. However, in the case of a PCSEL that oscillates at the M point, the wave number in the in-plane direction cannot become 0 due to diffraction, and diffraction in the direction perpendicular to the plane (Z-axis direction) does not occur. Therefore, since no laser light is output, M-point oscillation is not normally used in the PCSEL.

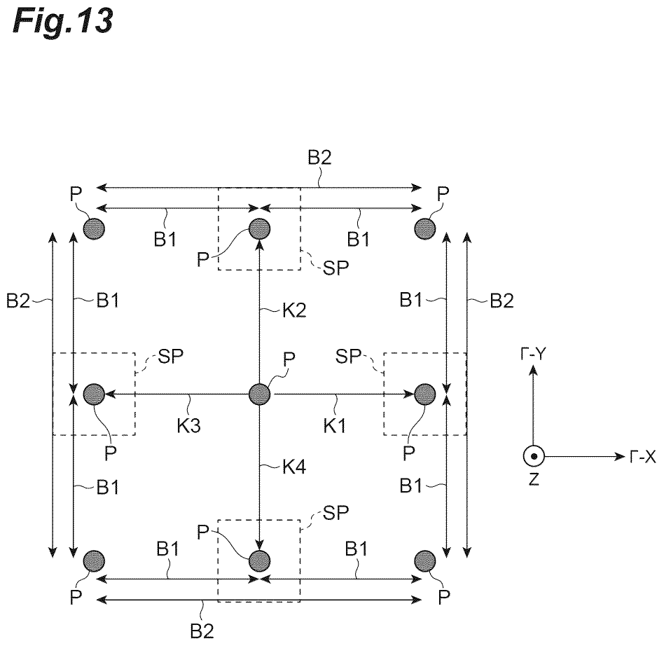

Next, an S-iPMSEL that oscillates at the τ point will be described. In addition, the conditions for τ-point oscillation are the same as those in the case of the PCSEL described above. FIG. 13 is a plan view showing a reciprocal lattice space regarding the phase modulation layer of the S-iPMSEL that oscillates at the τ point. The fundamental reciprocal lattice vector B1 is similar to that in the case of the PCSEL of τ-point oscillation (see FIG. 10), but each of the in-plane wave number vectors K1 to K4 is subjected to phase modulation by the rotation angle distribution ϕ(x, y) and has a wave number spread SP corresponding to the spread angle of the optical image. The wave number spread SP can be expressed as a rectangular region whose center is the tip of each of the in-plane wave number vectors K1 to K4 in the PCSEL of τ-point oscillation and whose side lengths in the x-axis direction and y-axis direction are 2Δkxmax and 2Δkymax, respectively. Due to the wave number spread SP, each of the in-plane wave number vectors K1 to K4 spreads over a rectangular range of (Kix+Δkx, Kiy+Δky) (i=1 to 4, Kix is the x-direction component of vector Ki, and Kiy is the y-direction component of vector Ki). Here, −Δkxmax Δkx Δkxmax, and −Δkymax Δky Δkymax. In addition, the magnitudes of Δkxmax and Δkymax are determined depending on the spread angle of the optical image. In other words, the magnitudes of Δkxmax and Δkymax depend on the optical image to be displayed on the semiconductor light emitting element 1A.

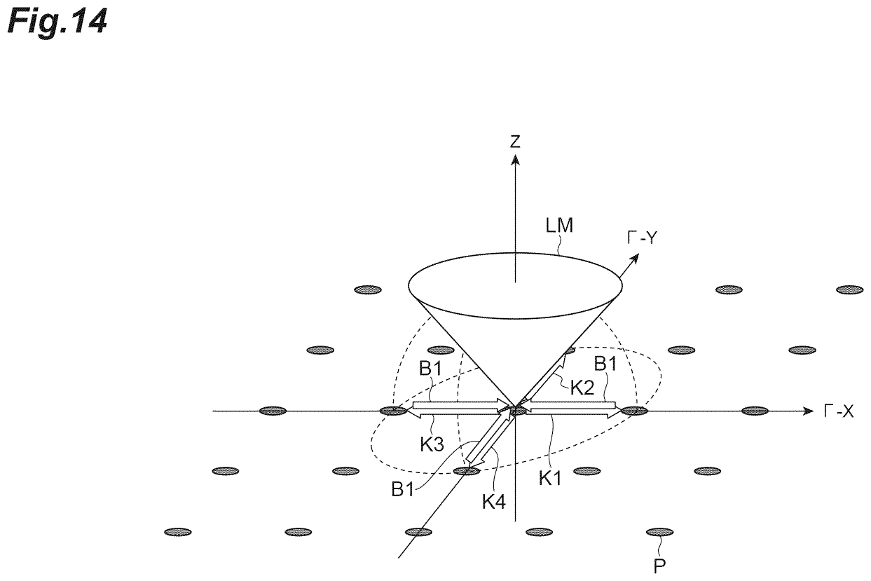

FIG. 14 is a three-dimensional perspective view of the reciprocal lattice space shown in FIG. 13. FIG. 14 shows a Z axis perpendicular to the directions of the τ-X axis and the τ-Y axis. This Z axis is the same as the Z axis shown in FIG. 1. As shown in FIG. 14, in the case of the S-iPMSEL that oscillates at the τ point, an optical image (beam pattern) LM having not only the 0th-order light in a direction perpendicular to the plane (Z-axis direction) but also the 1st-order light in a direction inclined with respect to the Z-axis direction and a two-dimensional spread including the 1st-order light is output.

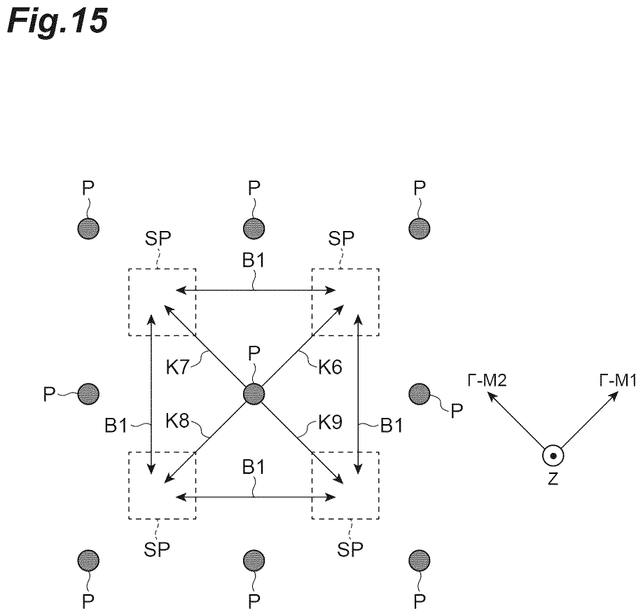

Next, the S-iPMSEL that oscillates at the M point will be described. In addition, the conditions for M-point oscillation are the same as those in the case of the PCSEL described above. FIG. 15 is a plan view showing a reciprocal lattice space regarding the phase modulation layer of the S-iPMSEL that oscillates at the M point. The fundamental reciprocal lattice vector B1 is the same as that in the case of the PCSEL of M-point oscillation (see FIG. 12), but each of the in-plane wave number vectors K6 to K9 has the wave number spread SP due to the rotation angle distribution ϕ(x, y). In addition, the shape and size of the wave number spread SP are the same as those in the case of the IF-point oscillation described above. Also in the S-iPMSEL, in the case of M-point oscillation, the magnitudes of the in-plane wave number vectors K6 to K9 (that is, the magnitude of the standing wave in the in-plane direction) is smaller than the magnitude of the fundamental reciprocal lattice vector B1. Therefore, the wave number in the in-plane direction cannot become 0 due to diffraction, and diffraction in the direction perpendicular to the plane (Z-axis direction) does not occur. Therefore, none of the 0th-order light in the direction perpendicular to the plane (Z-axis direction) and both the 1st-order light and the −1st-order light in the direction inclined with respect to the Z-axis direction are output.

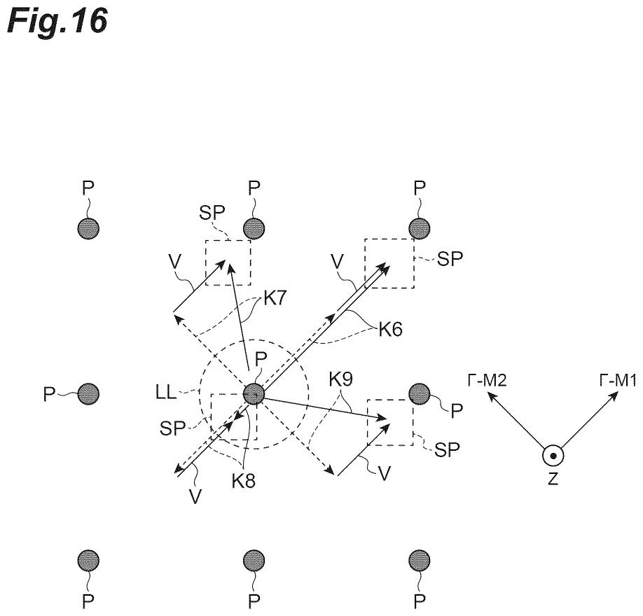

Here, in the present embodiment, a part of the 1st-order light and −1st-order light is output without outputting the 0th-order light by applying the following measures to the phase modulation layer 15A in the S-iPMSEL that oscillates at the point M. Specifically, as shown in FIG. 16, by adding a diffraction vector V having a fixed magnitude and direction to the in-plane wave number vectors K6 to K9, the magnitude of at least one of the in-plane wave number vectors K6 to K9 (in-plane wave number vector K8 in the diagram) is made smaller than 2π/λ. In other words, at least one (in-plane wave number vector K8) of the in-plane wave number vectors K6 to K9 after the addition of the diffraction vector V falls within a circular region (light line) LL with a radius of 2π/λ. In addition, the in-plane wave number vectors K6 to K9 shown by broken lines in FIG. 16 represent before the addition of the diffraction vector V, and the in-plane wave number vectors K6 to K9 shown by solid lines represent after the addition of the diffraction vector V. The light line LL corresponds to the total reflection conditions, and a wave number vector having a magnitude that falls within the light line LL has a component in the direction perpendicular to the plane (Z-axis direction). In one example, the direction of the diffraction vector V is along the τ-M1 axis or the τ-M2 axis, and its magnitude falls within the range of 2π/(√2)a−2π/λ to 2π/(√2)a+2π/λ. For example, the magnitude of the diffraction vector V is 2π/(√2)a.)

The magnitude and direction of the diffraction vector V to make at least one of the in-plane wave number vectors K6 to K9 fall within the light line LL will be considered. The following Equations (10) to (13) indicate the in-plane wave number vectors K6 to K9 before the diffraction vector V is added.

$$\begin{matrix}[ Equation 10 ] & \\ K 6 = ( \frac{π}{a} + Δ kx , \frac{π}{a} + Δ ky ) & ( 10 )\end{matrix}$$

$$\begin{matrix}[ Equation 11 ] & \\ K 7 = ( - \frac{π}{a} + Δ kx , \frac{π}{a} + Δ ky ) & ( 11 )\end{matrix}$$

$$\begin{matrix}[ Equation 12 ] & \\ K 8 = ( - \frac{π}{a} + Δ kx , - \frac{π}{a} + Δ ky ) & ( 12 )\end{matrix}$$

$$\begin{matrix}[ Equation 13 ] & \\ K 9 = ( \frac{π}{a} + Δ kx , - \frac{π}{a} + Δ ky ) & ( 13 )\end{matrix}$$

In addition, the spreads Δkx and Δky of the wave number vector satisfy the following Equations (14) and (15), respectively, and the maximum value Δkxmax of the spread in the x-axis direction and the maximum value Δkymax of the spread in the y-axis direction of the in-plane wave number vector are defined by the angular spread of the optical image of the design.

$$\begin{matrix}[ Equation 14 ] & \\ - Δ {kx}_{max} \leq Δ k x \leq Δ k {x}_{max} & ( 14 )\end{matrix}$$

$$\begin{matrix}[ Equation 15 ] & \\ - Δ {ky}_{max} \leq Δ ky \leq Δ {ky}_{max} & ( 15 )\end{matrix}$$

Here, when the diffraction vector V is expressed as the following Equation (16), the in-plane wave number vectors K6 to K9 after the diffraction vector V is added are expressed as the following Equations (17) to (20), respectively.

$$\begin{matrix}[ Equation 16 ] & \\ V = ( Vx , Vy ) & ( 16 )\end{matrix}$$

$$\begin{matrix}[ Equation 17 ] & \\ K 6 = ( \frac{π}{a} + Δ kx + Vx , \frac{π}{a} + Δ ky + Vy ) & ( 17 )\end{matrix}$$

$$\begin{matrix}[ Equation 18 ] & \\ K 7 = ( - \frac{π}{a} + Δ k x + Vx , \frac{π}{a} + Δ ky + Vy ) & ( 18 )\end{matrix}$$

$$\begin{matrix}[ Equation 19 ] & \\ K 8 = ( - \frac{π}{a} + Δ kx + Vx , - \frac{π}{a} + Δ ky + Vy ) & ( 19 )\end{matrix}$$

$$\begin{matrix}[ Equation 20 ] & \\ K 9 = ( \frac{π}{a} + Δ kx + Vx , - \frac{π}{a} + Δ ky + Vy ) & ( 20 )\end{matrix}$$

Considering that in Equations (17) to (20), any of the wave number vectors K6 to K9 falls within the light line LL, the relationship of the following Equation (21) is satisfied.

$$\begin{matrix}[ Equation 21 ] & \\ {( \pm \frac{π}{a} + Δ k x + V x )}^{2} + {( \pm \frac{π}{a} + Δ ky + Vy )}^{2} < {( \frac{2 π}{λ} )}^{2} & ( 21 )\end{matrix}$$

That is, by adding the diffraction vector V that satisfies Equation (21), any of the wave number vectors K6 to K9 falls within the light line LL, and a part of the 1st-order light and −1st-order light is output.

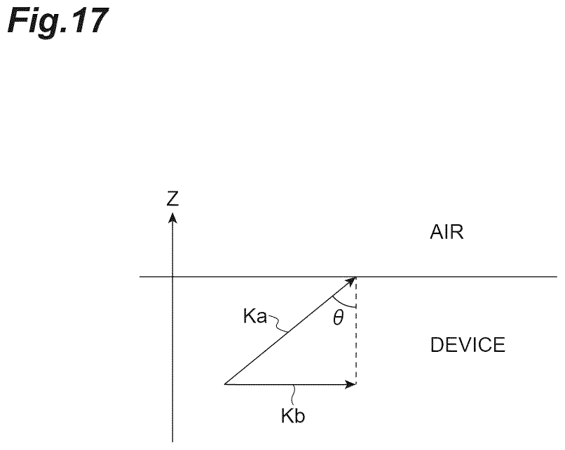

In addition, the reason why the size (radius) of the light line LL is set to 2π/λ is as follows. FIG. 17 is a diagram for schematically explaining the peripheral structure of the light line LL, and shows a boundary between a device and the air when viewed from a direction perpendicular to the Z-axis direction. The magnitude of the wave number vector of light in vacuum is 2n/λ. However, when light propagates in a device medium as shown in FIG. 17, the magnitude of a wave number vector Ka in a medium with a refractive index n is 2π/λ. At this time, in order for light to propagate across the boundary between the device and the air, wave number components parallel to the boundary should be continuous (wave number conservation law). In FIG. 17, when the wave number vector Ka and the Z axis form an angle θ, the length of a wave number vector Kb projected onto the plane (that is, an in-plane wave number vector) is (2πn/λ)sin θ. On the other hand, due to the relationship in which the refractive index of the medium is generally n>1, the wave number conservation law is not satisfied at angles where the in-plane wave number vector Kb in the medium is larger than 2π/λ. At this time, the light is totally reflected and cannot be extracted to the air side. The magnitude of the wave number vector corresponding to the total reflection conditions becomes the size of the light line LL, which is 2π/λ.

As an example of a specific method for adding the diffraction vector V to the in-plane wave number vectors K6 to K9, a method can be considered in which a rotation angle distribution ϕ₂(x, y) (second phase distribution) unrelated to the optical image is superimposed on a rotation angle distribution ϕ₁(x, y) (first phase distribution), which is the phase distribution according to the optical image. In this case, the rotation angle distribution ϕ(x, y) of the phase modulation layer 15A is expressed as the following equation.

$$ϕ ( x , y ) = {ϕ}_{1} ( x , y ) + {ϕ}_{2} ( x , y )$$

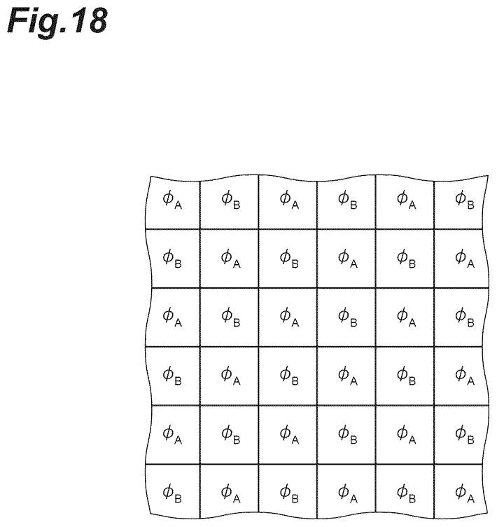

ϕ₁(x, y) corresponds to the phase of the complex amplitude when the optical image is Fourier-transformed as described above. In addition, ϕ₂(x, y) is a rotation angle distribution for adding the diffraction vector V that satisfies the above Equation (21). FIG. 18 is a diagram conceptually showing an example of the rotation angle distribution ϕ₂(x, y). As shown in FIG. 18, in this example, a first phase value ϕ_{A} and a second phase value ϕ_{B} different from the first phase value ϕ_{A} are arranged in a checkered pattern. In one practical example, the phase value ϕ_{A} is 0 (rad), and the phase value ϕ_{B} is π (rad). That is, the first phase value ϕ_{A} and the second phase value ϕ_{B} change by π. With such an arrangement of phase values, the diffraction vector V along the τ-M1 axis or the τ-M2 axis can be suitably realized. In the case of the checkered pattern described above, the first phase value ϕ_{A} and the second phase value ϕ_{B} exactly cancel out the wave number vectors K6 to K9 in FIG. 15 as V=(±π/a, ±π/a). In addition, by changing the arrangement direction of the phase values ϕ_{A} and ϕ_{B} from 45°, the direction of the diffraction vector V can be adjusted to any direction. In addition, the angle distribution O₂(x, y) of the diffraction vector V is expressed as an inner product between the diffraction vector V(Vx, Vy) and the position vector r(x, y), and is given by the following equation. ϕ₂(x, y)=V·r=Vxx+Vyy. Assuming that the center direction of the beam is a direction perpendicular to the plane, the diffraction vector V needs to cancel out the in-plane wave number vectors K6 to K9 at the M point. For this reason, V=(±π/a, ±π/a). On the other hand, if V is changed from this value, it is possible to emit a beam inclined from the direction perpendicular to the plane.

In addition, as long as the above-described structure includes the active layer 12 and the phase modulation layer 15A, the material system, film thickness, and layer structure can be changed in various ways. Here, the scaling law holds for a so-called square lattice photonic crystal laser when the perturbation from the virtual square lattice is 0. That is, when the wavelength is multiplied by a constant α, a similar standing wave state can be obtained by multiplying the entire square lattice structure by α. Similarly, in the present embodiment as well, it is possible to determine the structure of the phase modulation layer 15A based on the scaling law according to the wavelength. Therefore, by applying the scaling law according to the wavelength using the active layer 12 that emits light of blue, green, red, and the like, it is also possible to realize the semiconductor light emitting element 1A that outputs visible light.

When manufacturing the semiconductor light emitting element 1A, each compound semiconductor layer can be grown by using a metal organic chemical vapor deposition (MOCVD) method or a molecular beam epitaxy (MBE) method. In manufacturing the semiconductor light emitting element 1A using AlGaAs, the growth temperature of AlGaAs is 500° C. to 850° C., and 550° C. to 700° C. is used in experiments. During growth, TMA (trimethylaluminum) is used as a raw material for Al, TMG (trimethylgallium) and TEG (triethylgallium) are used as raw materials for gallium, AsH₃ (arsine) is used as a raw material for As, Si₂H₆ (disilane) is used as a raw material for n-type impurities, and DEZn (diethyl gallium) is used as a raw material for p-type impurities. In the growth of GaAs, TMG and arsine are used, but TMA is not used. InGaAs is manufactured using TMG, TMI (trimethylindium), and arsine. The insulating film may be formed by sputtering a target using its constituent materials as a raw material or using a PCVD (plasma CVD) method.

That is, for the semiconductor light emitting element 1A described above, first, an AlGaAs layer as the n-type cladding layer 11, an InGaAs/AlGaAs multiple quantum well structure as the active layer 12, and a GaAs layer as the base layer 15a of the phase modulation layer 15A are epitaxially grown sequentially on a GaAs substrate as the n-type semiconductor substrate 10 by using the MOCVD (metal organic chemical vapor deposition) method.

Then, another resist is applied to the base layer 15a, a two-dimensional fine pattern is drawn on the resist using an electron beam drawing device, and the resist is developed to form a two-dimensional fine pattern on the resist. Thereafter, by using the resist as a mask, the two-dimensional fine pattern is transferred onto the base layer 15a by dry etching to form holes, and then the resist is removed. In addition, a SiN layer or a SiO₂ layer may be formed on the base layer 15a using the PCVD method before forming the resist, a resist mask may be formed on the SiN layer or the SiO₂ layer, a fine pattern may be transferred onto the SiN layer or the SiO₂ layer using reactive ion etching (RIE), and dry etching may be performed after removing the resist. In this case, resistance to dry etching can be improved. These holes are used as the different refractive index regions 15b, or a compound semiconductor (AlGaAs) that becomes the different refractive index region 15b among these holes is regrown up to a depth equal to or greater than the depth of the holes. When the hole is used as the different refractive index region 15b, a gas such as air, nitrogen, hydrogen, or argon may be filled in the hole. Then, an AlGaAs layer as the cladding layer 13 and a GaAs layer as the contact layer 14 are sequentially formed by MOCVD, and the electrodes 16 and 17 are formed by using a vapor deposition method or a sputtering method. In addition, if necessary, the protective film 18 and the antireflection film 19 are formed by sputtering, a PCVD method, or the like.

In addition, when the phase modulation layer 15A is provided between the active layer 12 and the cladding layer 11, the phase modulation layer 15A may be formed on the cladding layer 11 before forming the active layer 12.

The effects obtained by the semiconductor light emitting element 1A according to the present embodiment described above will be described. In this semiconductor light emitting element 1A, each center of gravity G of the plurality of different refractive index regions 15b is arranged away from the corresponding lattice point O of the virtual square lattice, and has a rotation angle according to the optical image around the lattice point O. According to such a structure, the S-iPMSEL can output an optical image having any shape in a direction (Z-axis direction) perpendicular to the main surface 10a of the semiconductor substrate 10 or in a direction inclined with respect to the perpendicular direction. In addition, in this semiconductor light emitting element 1A, the lattice spacing a of the virtual square lattice and the emission wavelength λ of the active layer 12 satisfy the conditions for M-point oscillation. Normally, in the standing wave state of M-point oscillation, the light propagating within the phase modulation layer 15A is totally reflected. Therefore, the output of both signal light (1st-order light and −1st-order light) and 0th-order light is suppressed. However, in this semiconductor light emitting element 1A, on the reciprocal lattice space of the phase modulation layer 15A, the magnitude of at least one of the in-plane wave number vectors K6 to K9 in four directions each including the wave number spread Δk due to the rotation angle distribution ϕ(x, y) is smaller than 2π/λ (light line LL). In the S-iPMSEL, such adjustment of the in-plane wave number vectors K6 to K9 is possible by studying the rotation angle distribution ϕ(x, y), for example. Then, when the magnitude of at least one in-plane wave number vector is smaller than 2π/λ, the in-plane wave number vector has a component in the Z-axis direction, and as a result, a part of the signal light is output from the phase modulation layer 15A. However, since the 0th-order light is still confined in the plane in a direction that matches one of the four wave number vectors (±π/a, ±π a) forming the standing wave at the M point, the 0th-order light is not output from the phase modulation layer 15A into the light line. That is, according to the semiconductor light emitting element 1A of the present embodiment, since the 0th-order light included in the output of the S-iPMSEL is removed from the light line, only the signal light can be output into the light line.

In addition, as in the present embodiment, in the rotation angle distribution ϕ(x, y), the rotation angle distribution ϕ₁(x, y) according to the optical image and the rotation angle distribution ϕ₂(x, y) unrelated to the optical image may be superimposed. In this case, the rotation angle distribution ϕ₂(x, y) may be a rotation angle distribution for adding the diffraction vector V having a fixed magnitude and direction to the in-plane wave number vectors K6 to K9 in four directions due to the rotation angle distribution ϕ₁(x, y) on the reciprocal lattice space of the phase modulation layer 15A. Then, as a result of adding the diffraction vector V to the in-plane wave number vectors K6 to K9 in the four directions, the magnitude of at least one of the in-plane wave number vectors K6 to K9 in the four directions may become smaller than 2π/λ. In this manner, it is possible to easily realize a configuration in which the magnitude of at least one of the in-plane wave number vectors K6 to K9 in four directions each including the wave number spreads Δkx and Δky due to the rotation angle distribution ϕ(x, y) is smaller than 2π/λ(light line) on the reciprocal lattice space.

In addition, as in the present embodiment, the rotation angle distribution ϕ₂(x, y) may be a pattern in which the phase values ϕ_{A} and ϕ_{B} having different values are arranged in a checkered pattern. The diffraction vector V described above can be easily realized by such rotation angle distribution ϕ₂(x, y).

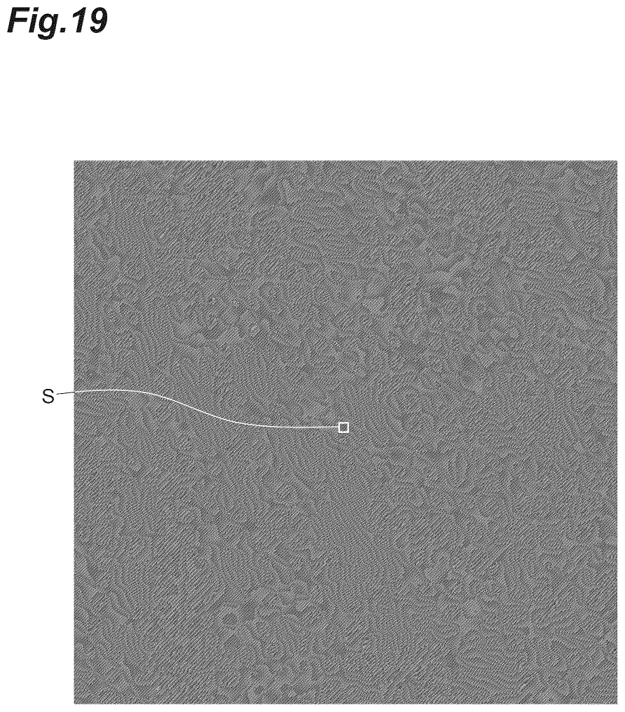

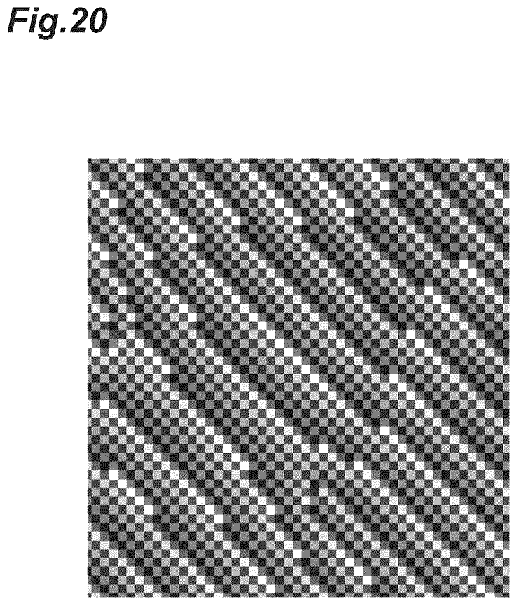

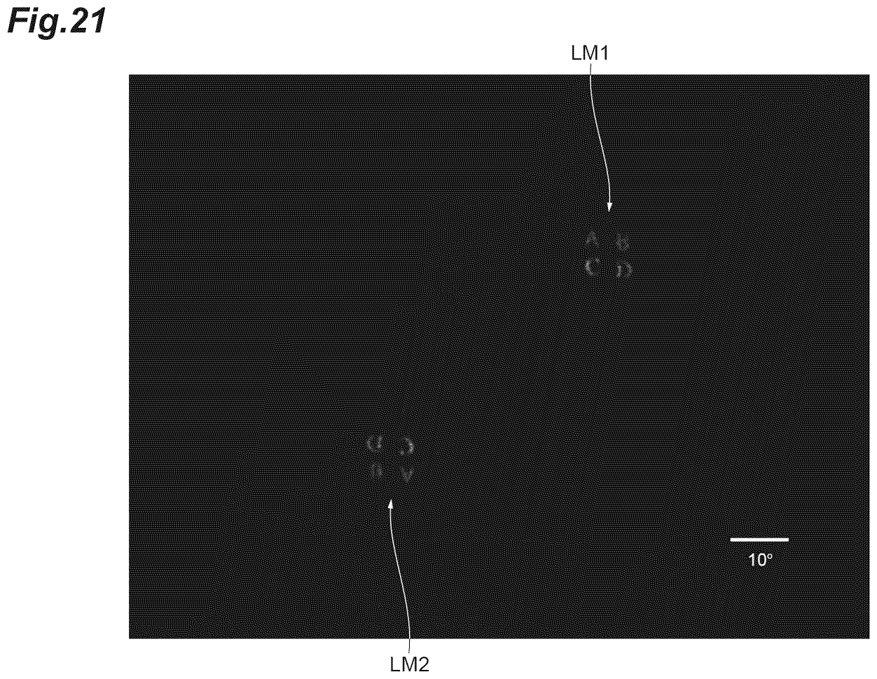

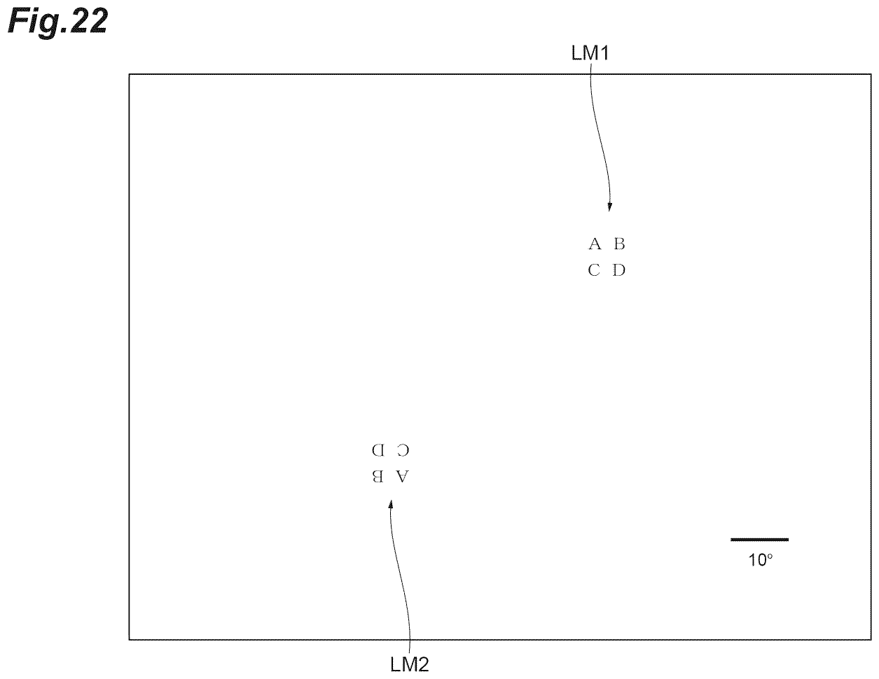

FIG. 19 is a diagram showing the rotation angle distribution ϕ(x, y) of the phase modulation layer 15A according to one practical example. In addition, FIG. 20 is an enlarged view of a portion S shown in FIG. 19. In FIGS. 19 and 20, the magnitude of the rotation angle is expressed by the shade of color, indicating that the darker the region, the larger the rotation angle (that is, the larger the phase angle). Referring to FIG. 20, it can be seen that patterns in which phase values having different values are arranged in a checkered pattern are superimposed. FIG. 21 shows a beam pattern (optical image) output from the semiconductor light emitting element 1A having the rotation angle distribution ϕ(x, y) shown in FIG. 19. In addition, FIG. 22 is a schematic diagram of the beam pattern shown in FIG. 21. The centers in FIGS. 21 and 22 correspond to the Z axis. As is apparent from FIGS. 21 and 22, the semiconductor light emitting element 1A outputs 1st-order light including a first optical image portion LM1 output in a first direction inclined with respect to the Z axis and −1st-order light, which is output in a second direction that is symmetrical to the first direction with respect to the Z axis and includes a second optical image portion LM2 that is rotationally symmetrical to the first optical image portion LM1 with respect to the Z axis, but does not output 0th-order light traveling on the Z axis.

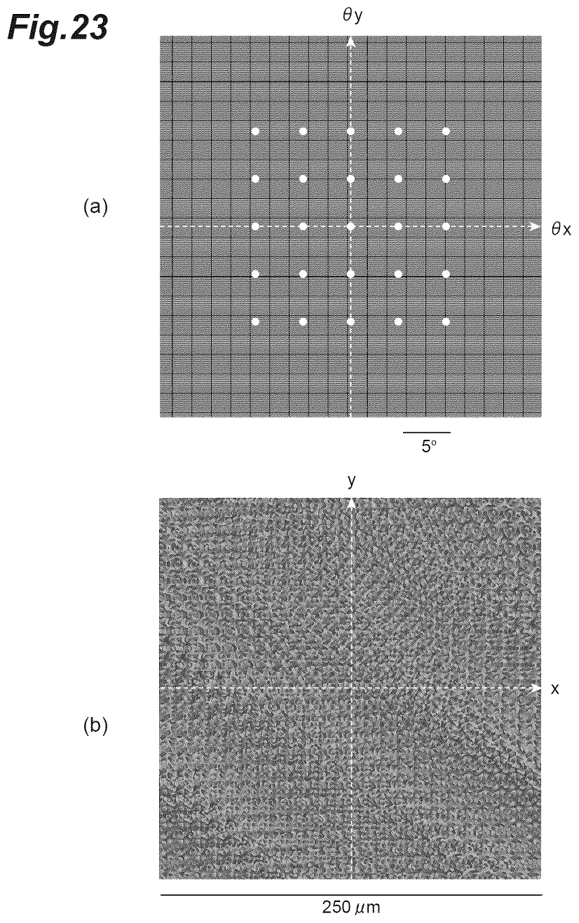

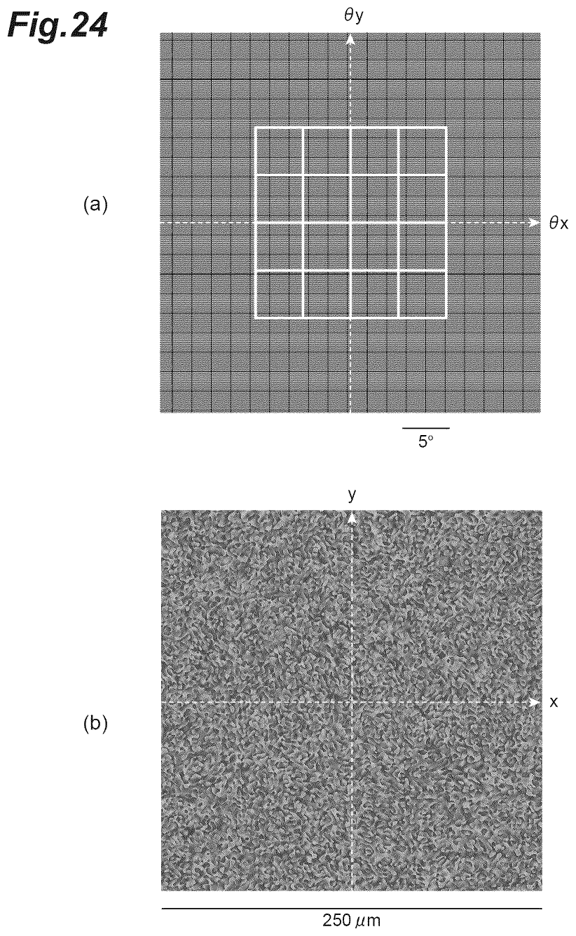

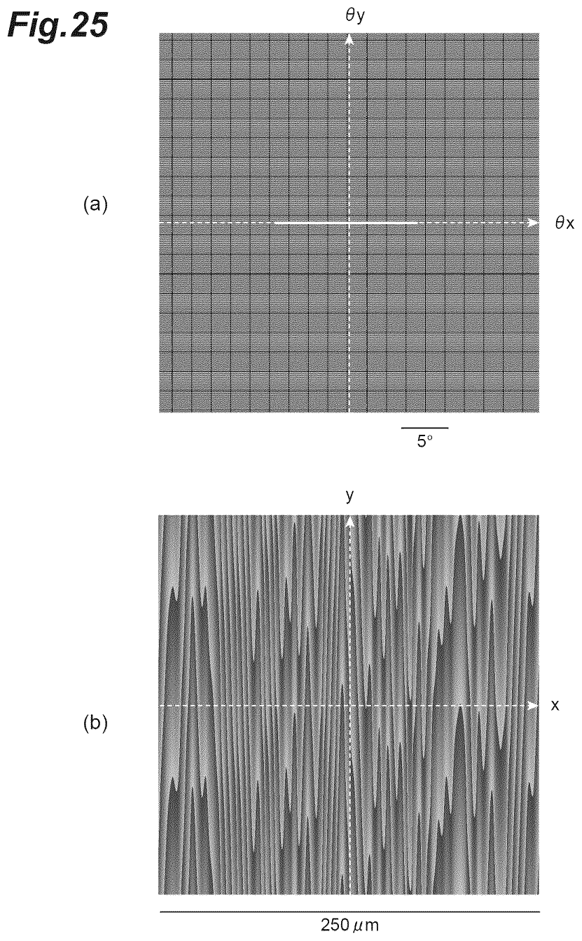

In the present embodiment, it is also possible to output a pattern that includes the Z axis and is symmetrical with respect to the Z axis. At this time, since there is no 0th-order light, there is no unevenness in the intensity of the pattern even on the Z axis. Examples of such beam pattern designs include 5×5 multipoint, mesh, and one-dimensional pattern. Schematic diagrams and phase distributions of these beam patterns are shown in FIGS. 23, 24, and 25. Such a beam pattern can be applied to, for example, object detection or three-dimensional measurement. Therefore, by using an eye-safe wavelength, it is also possible to provide a light source that is safe for the eyes.

### First Modification Example of Light Emitting Element

In the embodiment described above, when the wave number spread based on the angular spread of the optical image is included in a circle with a radius Δk centered on a predetermined point on the wave number space, the following can be simply considered. By adding the diffraction vector V to the in-plane wave number vectors K6 to K9 in the four directions, the magnitude of at least one of the in-plane wave number vectors K6 to K9 in the four directions is made smaller than 2π/λ(light line LL). This may also be thought as making the magnitude of at least one of the in-plane wave number vectors K6 to K9 in the four directions smaller than a value {(2π/λ)−Δk}, which is obtained by subtracting the wave number spread Δk from 2π/λ, by adding the diffraction vector V to the in-plane wave number vectors K6 to K9 in the four directions excluding the wave number spread Δk (that is, in-plane wave number vectors in the four directions in the square lattice PCSEL with M-point oscillation, see FIG. 12).

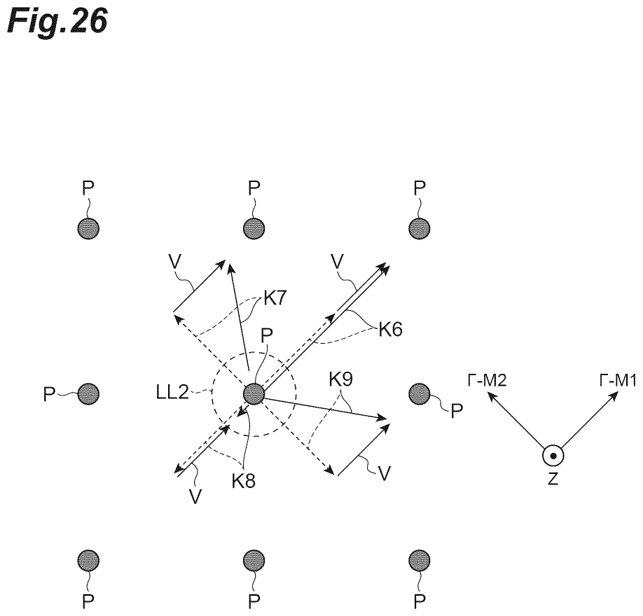

FIG. 26 is a diagram conceptually showing the above-described operation. As shown in the diagram, by adding the diffraction vector V to the in-plane wave number vectors K6 to K9 excluding the wave number spread Δk, the magnitude of at least one of the in-plane wave number vectors K6 to K9 is made smaller than {(2π/λ)−Δk}. In the diagram, a region LL2 is a circular region with a radius of {(2π/λ)−Δk}. In addition, the in-plane wave number vectors K6 to K9 shown by broken lines in FIG. 26 represent before the addition of the diffraction vector V, and in-plane wave number vectors K6 to K9 shown by solid lines represent after the addition of the diffraction vector V. The region LL2 corresponds to the total reflection conditions, and a wave number vector with a magnitude that falls within the region LL2 also propagates in the direction perpendicular to the plane (Z-axis direction).

In this modification example, the magnitude and direction of the diffraction vector V for making at least one of the in-plane wave number vectors K6 to K9 fall within the region LL2 will be described. The following Equations (22) to (25) show the in-plane wave number vectors K6 to K9 before the diffraction vector V is added.

$$\begin{matrix}[ Equation 22 ] & \\ K 6 = ( \frac{π}{a} , \frac{π}{a} ) & ( 22 )\end{matrix}$$

$$\begin{matrix}[ Equation 23 ] & \\ K 7 = ( - \frac{π}{a} , \frac{π}{a} ) & ( 23 )\end{matrix}$$

$$\begin{matrix}[ Equation 24 ] & \\ K 8 = ( - \frac{π}{a} , - \frac{π}{a} ) & ( 24 )\end{matrix}$$

$$\begin{matrix}[ Equation 25 ] & \\ K 9 = ( \frac{π}{a} , - \frac{π}{a} ) & ( 25 )\end{matrix}$$

Here, when the diffraction vector V is expressed as the above Equation (16), the in-plane wave number vectors K6 to K9 after the diffraction vector V is added are expressed as the following Equations (26) to (29), respectively.

$$\begin{matrix}[ Equation 26 ] & \\ K 6 = ( \frac{π}{a} + Vx , \frac{π}{a} + Vy ) & ( 26 )\end{matrix}$$

$$\begin{matrix}[ Equation 27 ] & \\ K 7 = ( - \frac{π}{a} + Vx , \frac{π}{a} + V y ) & ( 27 )\end{matrix}$$

$$\begin{matrix}[ Equation 28 ] & \\ K 8 = ( - \frac{π}{a} + Vx , - \frac{π}{a} + V y ) & ( 28 )\end{matrix}$$

$$\begin{matrix}[ Equation 29 ] & \\ K 9 = ( \frac{π}{a} + Vx , - \frac{π}{a} + V y ) & ( 29 )\end{matrix}$$

Considering that any one of the in-plane wave number vectors K6 to K9 falls within the region LL2 in Equations (26) to (29), the relationship of the following Equation (30) is satisfied.

$$\begin{matrix}[ Equation 30 ] & \\ {( \pm \frac{π}{a} + V x )}^{2} + {( \pm \frac{π}{a} + V y )}^{2} < {( \frac{2 π}{λ} - Δ k )}^{2} & ( 30 )\end{matrix}$$

That is, by adding the diffraction vector V that satisfies Equation (30), any of the in-plane wave number vectors K6 to K9 excluding the wave number spread Δk falls within the region LL2. Even in such a case, it is possible to output a part of the 1st-order light and −1st-order light without outputting the 0th-order light.

### Second Modification Example of Light Emitting Element

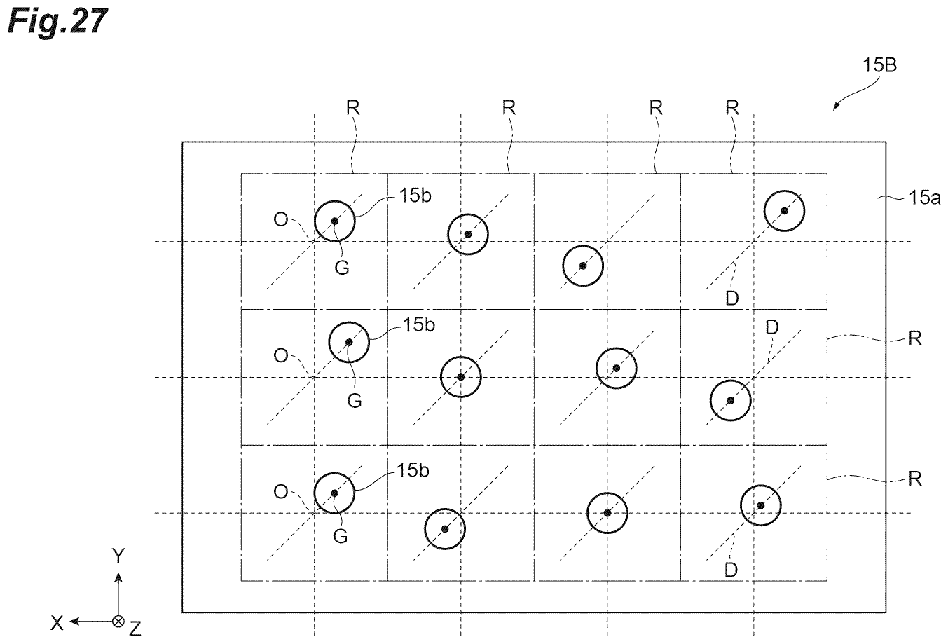

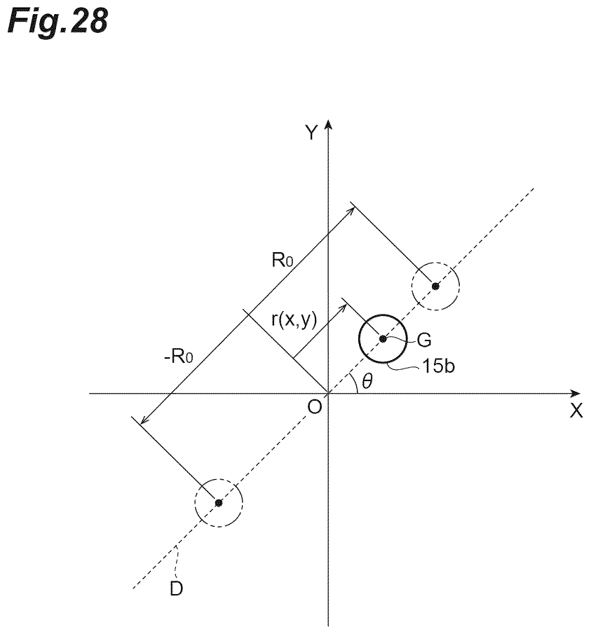

FIG. 27 is a plan view of a phase modulation layer 15B according to a second modification example of the above-described embodiment. In addition, FIG. 28 is a diagram showing the positional relationship of the different refractive index regions 15b in the phase modulation layer 15B. As shown in FIGS. 27 and 28, the center of gravity G of each different refractive index region 15b in this modification example is arranged on a straight line D. The straight line D is a straight line that passes through the corresponding lattice point O of each unit constituent region R and is inclined with respect to each side of the square lattice. In other words, the straight line D is a straight line that is inclined with respect to both the X axis and the Y axis. The angle of inclination of the straight line D with respect to one side (X axis) of the square lattice is 0. The inclination angle θ is fixed within the phase modulation layer 15B. The inclination angle θ satisfies 0°<θ<90°, and is θ=450 in one example. Alternatively, the inclination angle θ satisfies 180°<θ<270°, and is θ=225° in one example. When the inclination angle θ satisfies 0°<θ<90° or 180°<θ<270°, the straight line D extends from the first quadrant to the third quadrant of the coordinate plane defined by the X axis and the Y axis. Alternatively, the inclination angle θ satisfies 900<θ<180°, and is 0=135° in one example. Alternatively, the inclination angle θ satisfies 2700<θ<360°, and is 0=3150 in one example. When the inclination angle θ satisfies 900<θ<1800 or 2700<θ<360°, the straight line D extends from the second quadrant to the fourth quadrant of the coordinate plane defined by the X axis and the Y axis. Thus, the inclination angle θ is an angle excluding 0°, 90°, 180°, and 270°. Here, the distance between the lattice point O and the center of gravity G is defined as r(x, y). x indicates the position of the x-th lattice point on the X axis, and y indicates the position of the y-th lattice point on the Y axis. When the distance r(x, y) is a positive value, the center of gravity G is located in the first quadrant (or the second quadrant). When the distance r(x, y) is a negative value, the center of gravity G is located in the third quadrant (or the fourth quadrant). When the distance r(x, y) is 0, the lattice point O and the center of gravity G match each other. The inclination angle can be 45°, 135°, 225°, and 275°, and at these angles, only two of the four wave number vectors (for example, in-plane wave number vectors (±π/a, ±π/a)) forming the standing wave at the point M are phase-modulated, and the other two are not phase-modulated. Therefore, it is possible to form a stable standing wave.

The distance r(x, y) between the center of gravity G of each different refractive index region and the corresponding lattice point O of each unit constituent region R, which is shown in FIG. 27, is set individually for each different refractive index region 15b according to the phase pattern corresponding to the desired optical image. The phase pattern, that is, the distribution of the distance r(x, y) has a specific value for each position determined by the values of x and y, but is not necessarily expressed by a specific function. The distribution of the distance r(x, y) is determined from the phase distribution extracted from the complex amplitude distribution obtained by inverse Fourier transform of the desired optical image. That is, when the phase P(x, y) at predetermined coordinates (x, y) shown in FIG. 28 is P₀, the distance r(x, y) is set to 0. When the phase P(x, y) is π+P₀, the distance r(x, y) is set to the maximum value R₀, and when the phase P(x, y) is −π+P₀, the distance r(x, y) is set to the minimum value −R₀. Then, for the intermediate phase P(x, y), the distance r(x, y) is taken so that r(x, y)={P(x, y)−P₀}×R₀/π is satisfied. Here, the initial phase P₀ can be set arbitrarily. Assuming that the lattice spacing of the virtual square lattice is a, the maximum value R₀ of r(x, y) is within the range of the following Equation (31), for example.

$$\begin{matrix}[ Equation 31 ] & \\ 0 \leq {R}_{0} \leq \frac{a}{\sqrt{2}} & ( 31 )\end{matrix}$$

In addition, when calculating the complex amplitude distribution from the desired optical image, the reproducibility of the beam pattern is improved by applying an iterative algorithm such as a Gerchberg-Saxton (GS) method, which is generally used in calculations for hologram generation.

In this modification example, a desired optical image can be obtained by determining the distribution of the distance r(x, y) of the different refractive index region 15b of the phase modulation layer 15B. Under the same first to fourth prerequisites as in the embodiment described above, the phase modulation layer 15B satisfies the following conditions. That is, the corresponding different refractive index region 15b is arranged within the unit constituent region R(x, y) so that the distance r(x, y) from the lattice point O(x, y) to the center of gravity G of the corresponding different refractive index region 15b satisfies the following relationship.

$$r ( x , y ) = C \times ( P ( x , y ) - {P}_{0} )$$

C: constant of proportionality, for example, R₀/π
P₀: any constant, for example, 0

That is, the distance r(x, y) is set to 0 when the phase P(x, y) at predetermined coordinates (x, y) is P₀, is set to the maximum value R₀ when the phase P(x, y) is π+P₀, and is set to the minimum value −R₀ when the phase P(x, y) is −π+P₀. When it is desired to obtain a desired optical image, the optical image may be inversely Fourier-transformed, and the distribution of the distance r(x, y) according to the phase P(x, y) of the complex amplitude may be given to a plurality of different refractive index regions 15b. The phase P(x, y) and the distance r(x, y) may be proportional to each other.

Similarly to the embodiment described above, as a method to obtain the intensity distribution and the phase distribution from the complex amplitude distribution obtained by inverse Fourier transform, for example, an intensity distribution I(x, y) can be calculated by using the abs function of MathWorks' numerical analysis software “MATLAB”, and a phase distribution P(x, y) can be calculated by using the MATLAB's angle function. In addition, points to be noted in the case of calculation using general discrete Fourier transform (or fast Fourier transform) when calculating the phase distribution P (x, y) from the inverse Fourier transform result of the optical image and determining the distance r(x, y) of each different refractive index region 15b are the same as in the embodiment described above.

In this modification example as well, as in the embodiment described above, the lattice spacing a of the virtual square lattice and the emission wavelength λ of the active layer 12 satisfy the conditions for M-point oscillation. In addition, when considering the reciprocal lattice space in the phase modulation layer 15B, the magnitude of at least one of the in-plane wave number vectors in four directions each including the wave number spread due to the distribution of the distance r(x, y) is smaller than 2π/λ (light line).

To explain in detail, in this modification, a part of the 1st-order light and −1st-order light is output without outputting the 0th-order light into the light line by applying the following measures to the phase modulation layer 15B in the S-iPMSEL that oscillates at the point M. Specifically, as shown in FIG. 16, by adding the diffraction vector V having a fixed magnitude and direction to the in-plane wave number vectors K6 to K9, the magnitude of at least one of the in-plane wave number vectors K6 to K9 is made smaller than 2π/λ. In other words, at least one of the in-plane wave number vectors K6 to K9 after the addition of the diffraction vector V falls within a circular region (light line) LL with a radius of 2π/λ. That is, by adding the diffraction vector V that satisfies the above Equation (21), any of the in-plane wave number vectors K6 to K9 falls within the light line LL, and a part of the 1st-order light and −1st-order light is output.

Alternatively, as shown in FIG. 26 of the first modification example described above, the magnitude of at least one of the in-plane wave number vectors K6 to K9 in the four directions may be made smaller than a value {(2π/λ)−Δk}, which is obtained by subtracting the wave number spread Δk from 2π/λ, by adding the diffraction vector V to the in-plane wave number vectors K6 to K9 in the four directions excluding the wave number spread Δk (that is, in-plane wave number vectors in the four directions in the square lattice PCSEL with M-point oscillation, see FIG. 12). That is, by adding the diffraction vector V that satisfies the above Equation (30), any of the in-plane wave number vectors K6 to K9 falls within the region LL2, and a part of the 1st-order light and −1st-order light is output.

As an example of a specific method for adding the diffraction vector V to the in-plane wave number vectors K6 to K9, a method can be considered in which the distance distribution r₂(x, y) (second phase distribution) unrelated to the optical image is superimposed on the distance distribution r₁(x, y) (first phase distribution), which is the phase distribution according to the optical image. In this case, the distance distribution r(x, y) of the phase modulation layer 15B is expressed as the following equation.

$$r ( x , y ) = {r}_{1} ( x , y ) + {r}_{2} ( x , y )$$

r₁(x, y) corresponds to the phase of the complex amplitude when the optical image is Fourier-transformed as described above. In addition, r₂(x, y) is a distance distribution for adding the diffraction vector V that satisfies the above Equation (30). In addition, a specific example of the distance distribution r₂(x, y) is the same as that shown in FIG. 18.

In this modification example, the center of gravity G of each different refractive index region 15b is arranged on the straight line D that passes through the lattice point O of the virtual square lattice and is inclined with respect to the square lattice. Then, the distance r(x, y) between the center of gravity G of each different refractive index region 15b and the corresponding lattice point O is individually set according to the optical image. According to such a structure, as in the above-described embodiment in which the center of gravity G of each different refractive index region 15b has a rotation angle according to the optical image around each lattice point O, the S-iPMSEL can output an optical image having any shape in the Z-axis direction and a direction inclined with respect to the Z-axis direction. In addition, in this modification example as well, the lattice spacing a of the virtual square lattice and the emission wavelength λ of the active layer 12 satisfy the conditions for M-point oscillation, and on the reciprocal lattice space of the phase modulation layer 15B, a plane wave forming a standing wave is phase-modulated by the distribution of the distance r(x, y) and the magnitude of at least one of the in-plane wave number vectors K6 to K9 in the four directions each including the wave number spread Δk due to the angular spread of the optical image is smaller than 2π/λ (light line). Alternatively, by adding the diffraction vector V to the in-plane wave number vectors K6 to K9 in the four directions excluding the wave number spread Δk, the magnitude of at least one in-plane wave number vector is made smaller than the value {(2π/λ)−Δk}, which is obtained by subtracting the wave number spread Δk from 2π/λ. Therefore, since the 0th-order light included in the output of the S-iPMSEL is removed from the light line, only the signal light can be output.

### Third Modification Example of Light Emitting Element

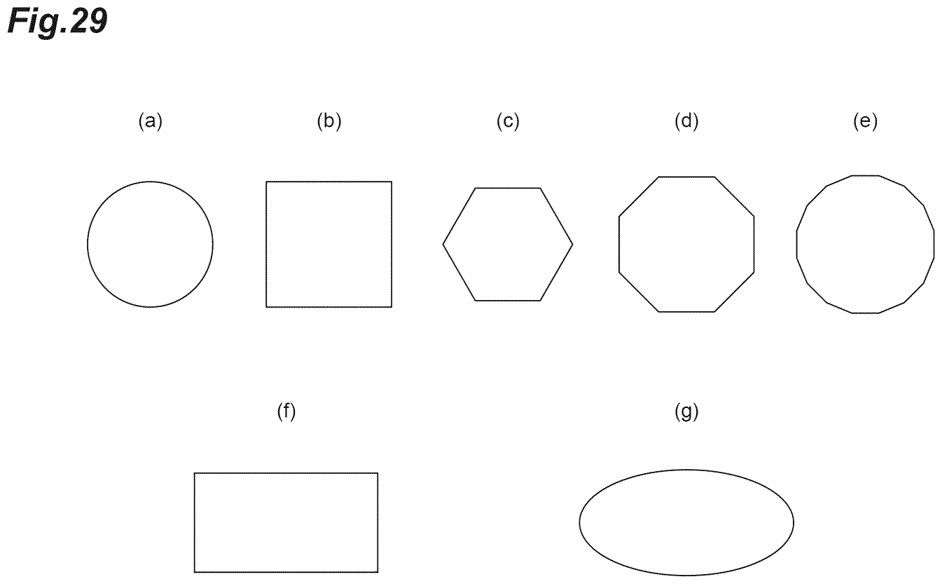

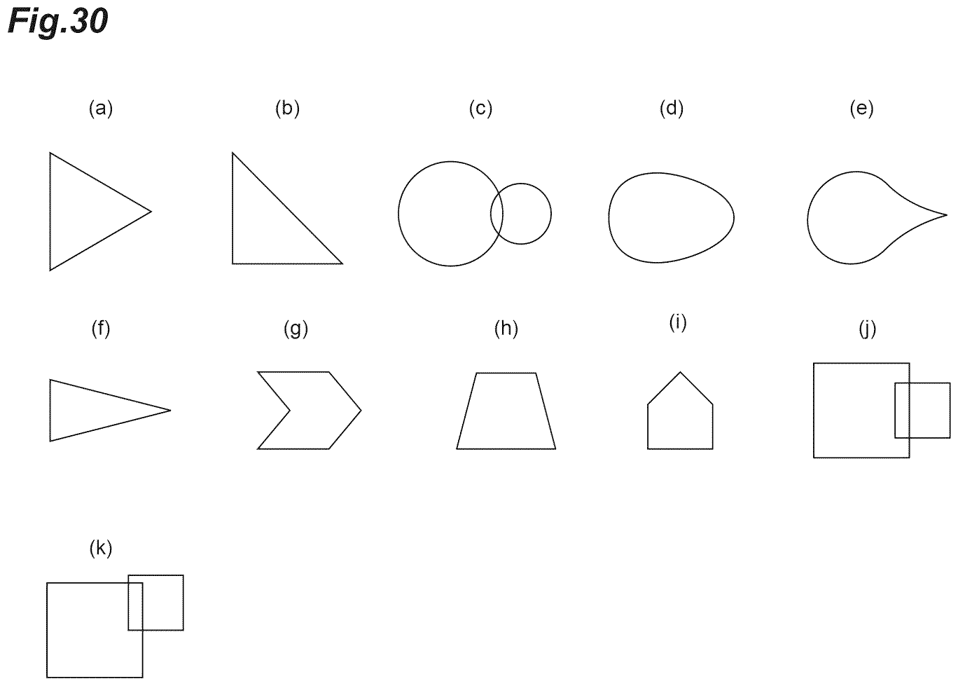

FIGS. 29 and 30 are plan views showing examples of the shape of the different refractive index region 15b in the XY plane. In the above embodiment and each modification example, examples are shown in which the shape of the different refractive index region 15b in the XY plane is a circle. However, the different refractive index region 15b may have a shape other than the circle. For example, the shape of the different refractive index region 15b in the XY plane may have mirror symmetry (line symmetry). Here, mirror symmetry (line symmetry) means that the planar shape of the different refractive index region 15b located on one side of a predetermined straight line along the XY plane and the planar shape of the different refractive index region 15b located on the other side of the straight line can be mirror-symmetrical (line-symmetrical) with respect to each other with the straight line interposed therebetween. Examples of the shape with mirror symmetry (line symmetry) include a perfect circle shown in FIG. 29(a), a square shown in FIG. 29(b), a regular hexagon shown in FIG. 29(c), a regular octagon shown in FIG. 29(d), a regular hexagon shown in FIG. 29(e), a rectangle shown in FIG. 29(f), and an ellipse shown in FIG. 29(g). Thus, the shape of the different refractive index region 15b in the XY plane has mirror symmetry (line symmetry). In this case, since each unit constituent region R of the virtual square lattice of the phase modulation layer has a simple shape, the direction and position of the center of gravity G of the corresponding different refractive index region 15b from the lattice point O can be determined with high accuracy. Therefore, it is possible to perform patterning with high accuracy.

In addition, the shape of the different refractive index region 15b in the XY plane may be a shape that does not have a rotational symmetry of 180°. Examples of such a shape include an equilateral triangle shown in FIG. 30(a), a right isosceles triangle shown in FIG. 30(b), a shape shown in FIG. 30(c) in which two circles or ellipses partially overlap each other, a shape (egg shape) shown in FIG. 30(d) in which an ellipse is deformed so that the dimension in the short axis direction near one end along the long axis of the ellipse is smaller than the dimension in the short axis direction near the other end, a shape (teardrop shape) shown in FIG. 30(e) in which one end along the long axis of an ellipse is deformed into a pointed end protruding along the long axis direction, an isosceles triangle shown in FIG. 30(f), a shape (arrow shape) shown in FIG. 30(g) in which one side of a rectangle is recessed in a triangular shape and the opposite side is pointed in a triangular shape, a trapezoid shown in FIG. 30(h), a pentagon shown in FIG. 30(i), a shape shown in FIG. 30(j) in which parts of two rectangles overlap each other, and a shape shown in FIG. 30(k) in which parts of two rectangles overlap each other and do not have mirror symmetry. Thus, since the shape of the different refractive index region 15b in the XY plane does not have a rotational symmetry of 180°, it is possible to obtain a higher optical output.

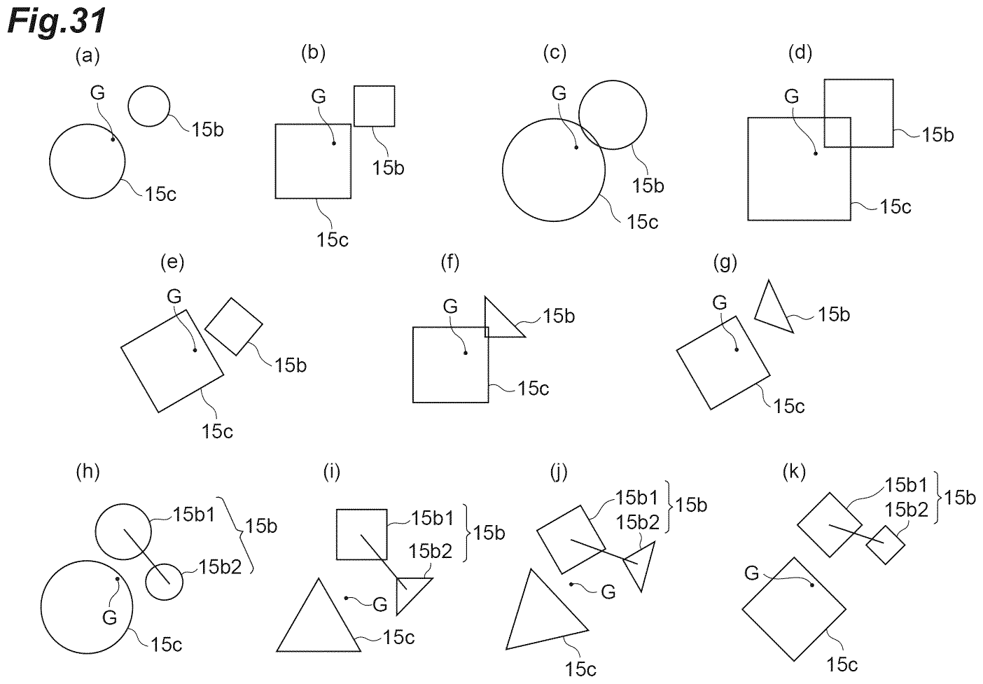

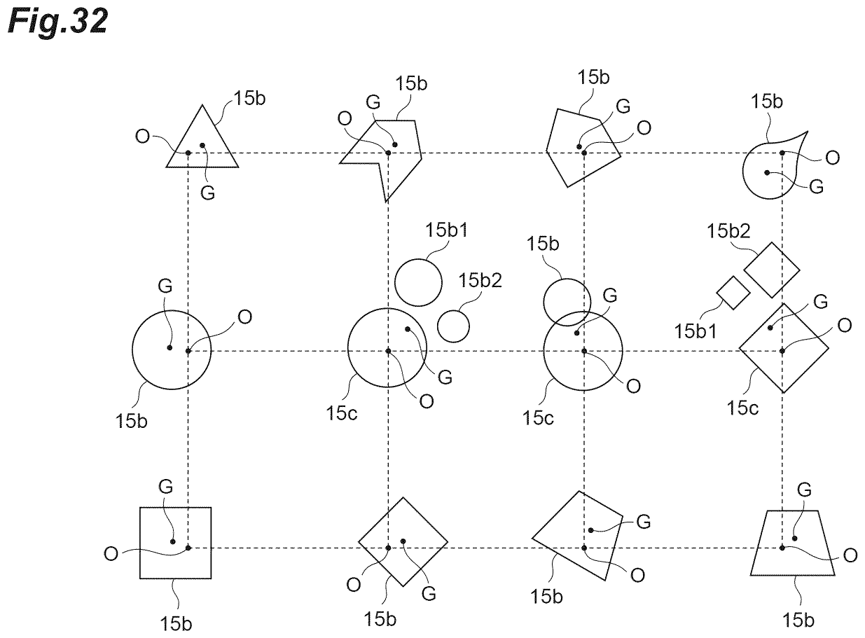

FIGS. 31 and 32 are plan views showing other examples of the shape of the different refractive index region in the XY plane. In this example, a plurality of different refractive index regions 15c that are different from the plurality of different refractive index regions 15b are further provided. Each different refractive index region 15c is formed of a second refractive index medium having a different refractive index from the first refractive index medium of the base layer 15a. Similarly to the different refractive index region 15b, the different refractive index region 15c may be a vacancy, or may be formed by filling the vacancy with a compound semiconductor. The different refractive index region 15c is provided so as to correspond to the different refractive index regions 15b on a one-to-one basis. Then, the center of gravity G of the sum of the different refractive index regions 15b and 15c is located on the straight line D that crosses the lattice point O of the unit constituent region R forming the virtual square lattice. In addition, both the different refractive index regions 15b and 15c are included within the range of the unit constituent region R forming the virtual square lattice. The unit constituent region R is a region surrounded by the straight line for bisection between the lattice points of the virtual square lattice.

The planar shape of the different refractive index region 15c is, for example, a circle, but can have various shapes like the different refractive index region 15b. FIGS. 31(a) to 31(k) show examples of the shapes and relative relationships of the different refractive index regions 15b and 15c in the XY plane. FIGS. 31(a) and 31(b) show a form in which the different refractive index regions 15b and 15c have the same shape. FIGS. 31(c) and 31(d) show a form in which the different refractive index regions 15b and 15c have the same shape and partially overlap each other. FIG. 31(e) shows a form in which the different refractive index regions 15b and 15c have the same shape and are rotated. FIG. 31(f) shows a form in which the different refractive index regions 15b and 15c have different shapes. FIG. 31(g) shows a form in which the different refractive index regions 15b and 15c have different shapes and the different refractive index regions 15b and 15c are spaced apart from each other.

In addition, as shown in FIGS. 31(h) to 31(k), the different refractive index region 15b may include two regions 15b1 and 15b2 spaced apart from each other. At this time, it is considered that the center of gravity of the sum of the regions 15b1 and 15b2 corresponds to the center of gravity of the single different refractive index region 15b. In addition, in this case, as shown in FIGS. 31(h) and 31(k), the regions 15b1 and 15b2 and the different refractive index region 15c may have the same shape. Alternatively, as shown in FIGS. 31(i) and 31(j), the shapes of two of the regions 15b1 and 15b2 and the different refractive index region 15c may be different from the other one.

The shapes of different refractive index regions in the XY plane may be the same between the lattice points. That is, different refractive index regions can have the same shape at all lattice points, and can be superimposed on each other between the lattice points by a translation operation or by translational and rotational operations. In this case, variations in phase angle due to variations in shape can be suppressed, and a beam pattern can be emitted with high accuracy. Alternatively, the shapes of different refractive index region in the XY plane do not necessarily have to be the same between the lattice points. For example, as shown in FIG. 32, the shapes may be different between adjacent lattice points.

### Fourth Modification Example of Light Emitting Element

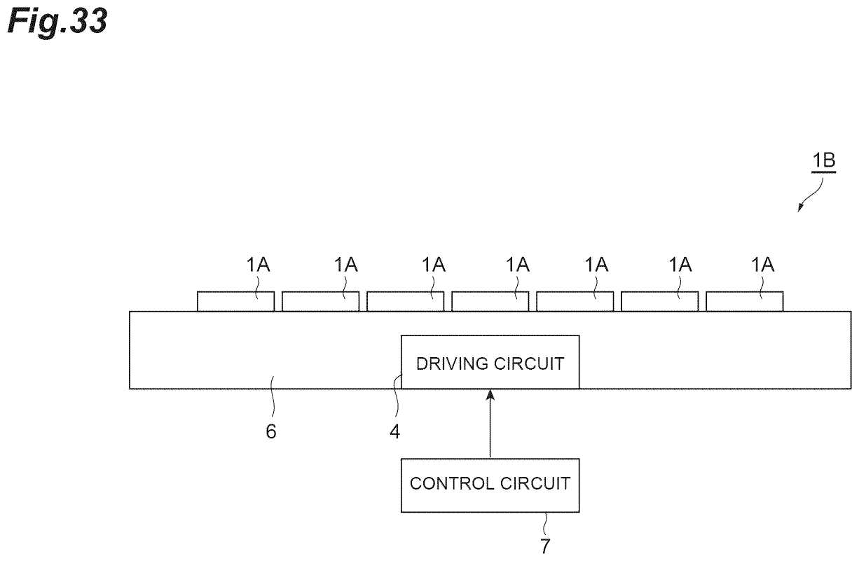

FIG. 33 is a diagram showing the configuration of alight emitting device 1B according to a fourth modification example. This light emitting device 1B includes a support substrate 6, a plurality of semiconductor light emitting elements 1A arranged one-dimensionally or two-dimensionally on the support substrate 6, and a drive circuit 4 for individually driving the plurality of semiconductor light emitting elements 1A. The configuration of each semiconductor light emitting element 1A is the same as that in the embodiment described above. However, the plurality of semiconductor light emitting elements 1A may include a laser element that outputs an optical image in the red wavelength range, a laser element that outputs an optical image in the blue wavelength range, and a laser element that outputs an optical image in the green wavelength range. The laser element that outputs an optical image in the red wavelength range is formed of, for example, GaAs-based semiconductor. The laser element that outputs an optical image in the blue wavelength range and a laser element that outputs an optical image in the green wavelength range are formed of, for example, nitride-based semiconductor. The drive circuit 4 is provided on the back surface or inside the support substrate 6, and drives each semiconductor light emitting element 1A individually. The drive circuit 4 supplies a drive current to each semiconductor light emitting element 1A according to an instruction from a control circuit 7.

By providing a plurality of semiconductor light emitting elements 1A that are individually driven and extracting a desired optical image from each semiconductor light emitting element 1A as in this modification example, a head-up display and the like can be suitably realized by appropriately driving necessary elements for a module in which semiconductor light emitting elements corresponding to a plurality of patterns are arranged in advance. In addition, since the plurality of semiconductor light emitting elements 1A include a laser element that outputs an optical image in the red wavelength range, a laser element that outputs an optical image in the blue wavelength range, and a laser element that outputs an optical image in the green wavelength range, a color head-up display and the like can be suitably realized.

The light emitting element according to the present disclosure is not limited to the embodiment described above, and various modifications can be made. For example, in the embodiment described above, laser elements formed of GaAs-based, InP-based, and nitride-based (particularly GaN-based) compound semiconductors are exemplified. However, the present disclosure can be applied to laser elements formed of various semiconductor materials other than these.

In addition, in the above embodiment, an example in which the active layer provided on the same semiconductor substrate as the phase modulation layer is used as a light emitting portion has been described. However, in the present disclosure, the light emitting portion may be provided separately from the semiconductor substrate. As long as the light emitting portion is optically coupled to the phase modulation layer and supplies light to the phase modulation layer, the same effects as in the above embodiment can be suitably achieved even with such a configuration.

### One Embodiment of Method for Manufacturing Light Emitting Element

Subsequently, one embodiment of a method for manufacturing the semiconductor light emitting element 1A will be described. In the manufacturing method according to the present embodiment, first, the phase modulation layer 15A is designed. That is, the manufacturing method according to the present embodiment includes a method for designing the phase modulation layer 15A.

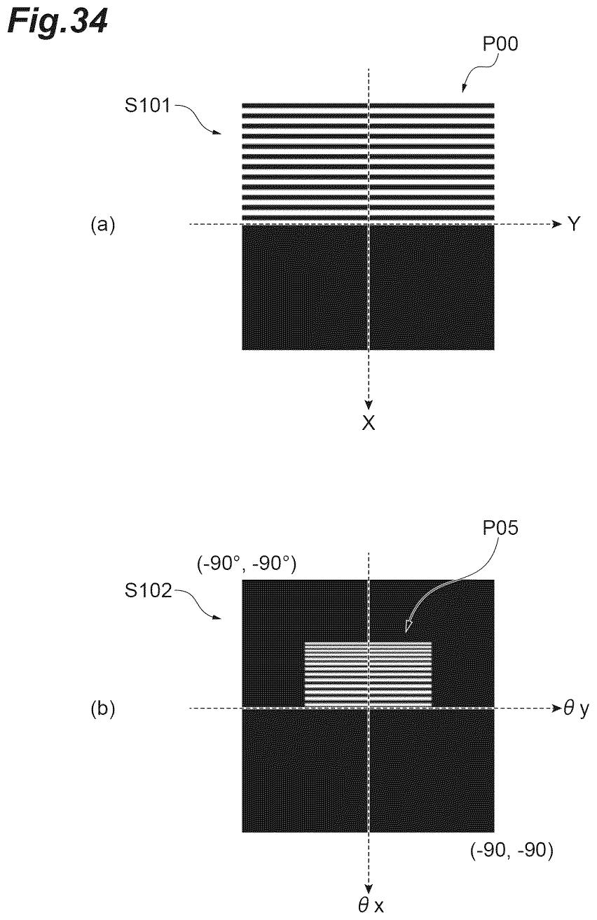

FIG. 34 is a diagram showing one step of a phase modulation layer design method according to the present embodiment. FIG. 34 shows a designed optical image on a predetermined plane. FIG. 34(a) is a designed optical image on the XY plane on a flat screen to be projected onto. The designed optical image is a desired optical image output from the semiconductor light emitting element 1A, and can be set arbitrarily. In other words, in the design method according to the present embodiment, first, a desired optical image to be output from the semiconductor light emitting element 1A is set (step S101). Here, an example will be given in which a (sinusoidal wave or rectangular wave) striped optical image (pattern P00) is set. Although only the 1st-order light is considered herein, the −1st-order light may also be considered. In the pattern P00 (optical image), a portion displayed white is a group of bright spots.

In the design method according to the present embodiment, as shown in FIG. 34(b), the pattern P00 in real space is then converted into an optical image (pattern P05) on the θₓ-θ_{y} plane in the angular space (step S102). The angular space θₓ-θ_{y} and the coordinates Xs-Ys on the plane screen located at the distance D are expressed by the following Equation (32) using the tilt angle θₜᵢₗₜ from the Z axis and the rotation angle θᵣₒₜ from the X axis shown in the above Equations (1) to (3). Therefore, θₓ and θ_{y} are expressed by the following Equation (33).

$$\begin{matrix}[ Equation 32 ] & \\ ( \begin{matrix}{X}_{S} \\ {Y}_{S}\end{matrix} ) = ( \begin{matrix}D tan {θ}_{tilt} cos {θ}_{rot} \\ D tan {θ}_{tilt} sin {θ}_{rot}\end{matrix} ) = ( \begin{matrix}D tan {θ}_{X} \\ D tan {θ}_{Y}\end{matrix} ) . & ( 32 )\end{matrix}$$

$$\begin{matrix}[ Equation 33 ] & \\ ( \begin{matrix}{θ}_{x} \\ {θ}_{y}\end{matrix} ) = ( \begin{matrix}{tan}^{- 1} ( tan {θ}_{tilt} cos {θ}_{rot} ) \\ {tan}^{- 1} ( tan {θ}_{tilt} sin {θ}_{rot} )\end{matrix} ) . & ( 33 )\end{matrix}$$

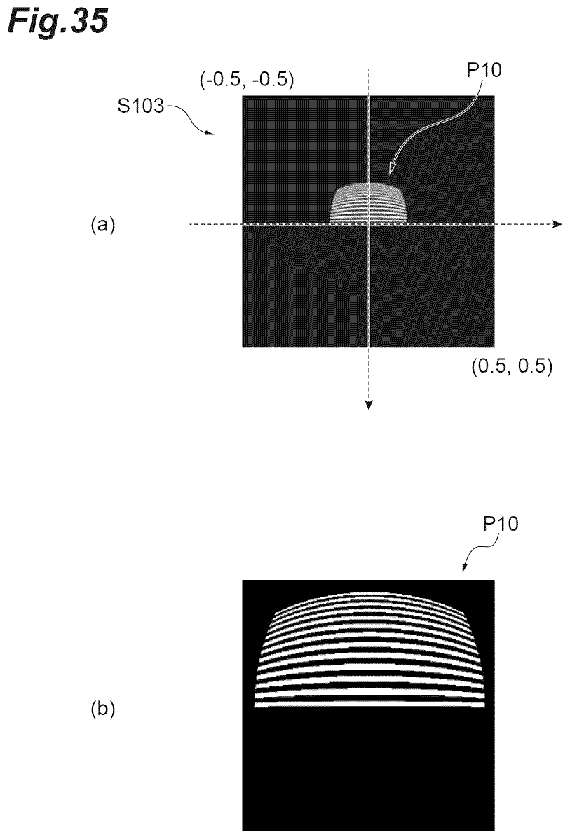

Subsequently, as shown in FIG. 35, the pattern P05 (optical image) on the angular space is converted into a pattern P10 on the Kₓ-K_{y} plane in the wave number space (step S103). In addition, FIG. 35(b) is an enlarged view of FIG. 35(a). The relationship between the wave number space defined by the Kx axis and the Ky axis the XYZ coordinate system and the spherical coordinate system is shown in the above Equations (1) to (5). The pattern P10 on the wave number space is one of the design patterns for designing the distribution of the different refractive index regions 15b in the phase modulation layer 15A.

That is, the design method according to the present embodiment includes a step of generating a design pattern of the phase modulation layer 15A (steps S101 to S103 and step S104 described later: generation step). More specifically, here, a first design pattern (pattern P10) including bright spots corresponding to the bright spots of the optical image (pattern P00), which is a pattern for designing the different refractive index region 15b so that the distribution of the different refractive index region 15b becomes a distribution corresponding to the optical image (pattern P00) output from the semiconductor light emitting element 1A, is generated (step S103: first step).

At this time, in step S103, when a virtual square lattice is set in the XY plane, the pattern P10 can be generated so that the center of gravity G of each different refractive index region 15b is arranged away from the corresponding lattice point O and has a rotation angle ϕ according to the phase distribution corresponding to the optical image around the lattice point O and the lattice spacing a of the virtual square lattice and the emission wavelength λ satisfy the conditions for M-point oscillation.

In the example of the embodiment related to the semiconductor light emitting element 1A described above, the complex amplitude F(x, y) is calculated by performing a two-dimensional inverse discrete Fourier transform expressed by the above Equation (6) on the pattern P10 on the wave number space, the rotation angle distribution ϕ(x, y) of the different refractive index region 15b is acquired by using the phase term P(x, y) of the complex amplitude F(x, y), and the phase modulation layer 15A having the different refractive index region 15b corresponding to the rotation angle distribution ϕ(x, y) is manufactured.

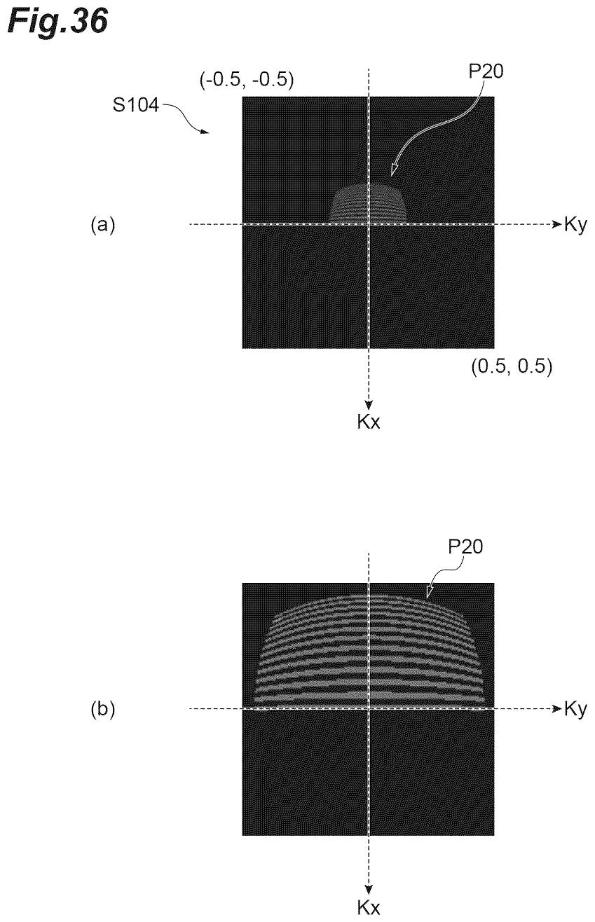

On the other hand, in the design method according to the present embodiment, noise is reduced by thinning out bright spots. That is, in this design method, as shown in FIG. 36, in the subsequent step, a new pattern (second design pattern) P20 on the wave number space is generated by thinning out some of the bright spots included in the pattern P10 (step S104: second step). FIG. 36 shows a new pattern generated by thinning out bright spots. FIG. 36(b) is an enlarged view of FIG. 36(a). Since some of the bright spots in the pattern P10 are thinned out, the pattern P20 is dark as a whole in the illustration.

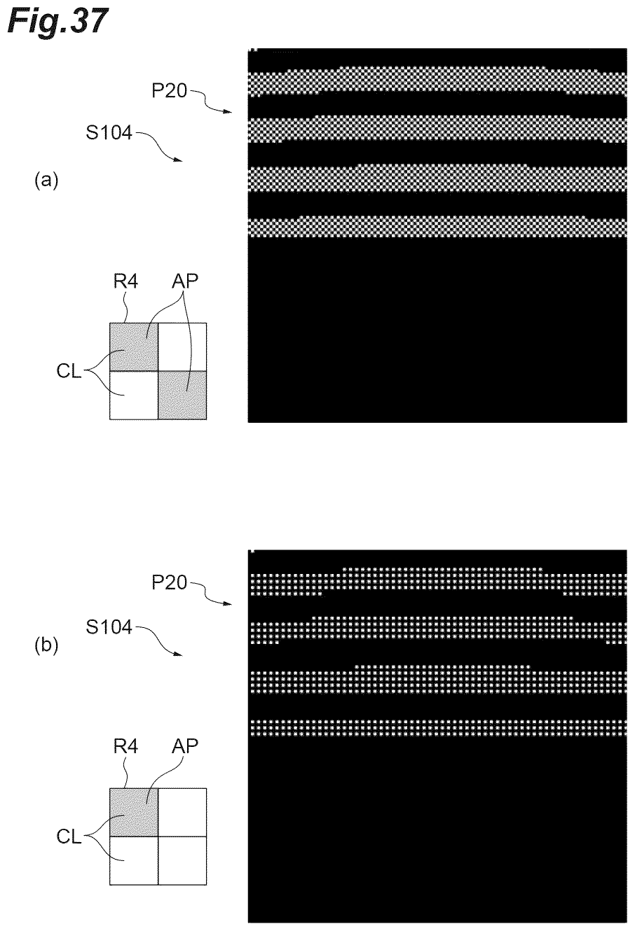

This step S104 will be described more specifically. In this step S104, the pattern P20 is generated from the pattern P10 by dividing the pattern P10 into a plurality of regions and thinning out at least one of a plurality of bright spots included in each of the regions. In the example of FIG. 37(a), the pattern P10 is divided into regions R4 formed of wave number data CL indicating four bright spots two-dimensionally adjacent to each other on the wave number space. The region R4 is a region formed of 2×2 wave number data CL (pixels) along the Kₓ axis and the K_{y} axis. Then, in this example, two of the pieces of wave number data CL in the region RA are thinned out to generate the pattern P20.

As a result, in the pattern P20, two bright spots AP remain in one region R4. In particular, in the example of FIG. 37(a), bright spots are thinned out so that the bright spots AP remain side by side in a direction crossing the Kₓ axis and the K_{y} axis in the Kₓ-K_{y} plane. In addition, thinning out bright spots means, in the pattern P10, making the value of the wave number data CL corresponding to the bright spots of the pattern P00 relatively small (for example, set to 0).

In the example of FIG. 37(b) as well, similarly to FIG. 37(a), the pattern P10 is divided into regions R4 formed of the wave number data CL indicating four bright spots two-dimensionally adjacent to each other on the wave number space. Then, three of the pieces of wave number data CL in the region R4 are thinned out. As a result, in the pattern P20, one bright spot AP remains in one region R4. In addition, the size of the region R4 is not limited to the above-described 2×2, and any other size such as 3×3 can be selected. In addition, the thinning interval and the like are also any thinning interval and the like. On the other hand, as the amount of thinning-out increases, the amount of information of the original pattern P10 that is lost increases. Therefore, since the thinning-out causes brightness unevenness or a decrease in the amount of light, it is not recommended to perform thinning-out in the region R4 indefinitely. In the case of 2×2 shown in FIG. 37, suitable results are obtained. The design method according to the present embodiment includes the above-described steps S101 to S104. Subsequently, the phase modulation layer 15A and the semiconductor light emitting element 1A are manufactured based on the design pattern obtained by the design method according to the present embodiment.

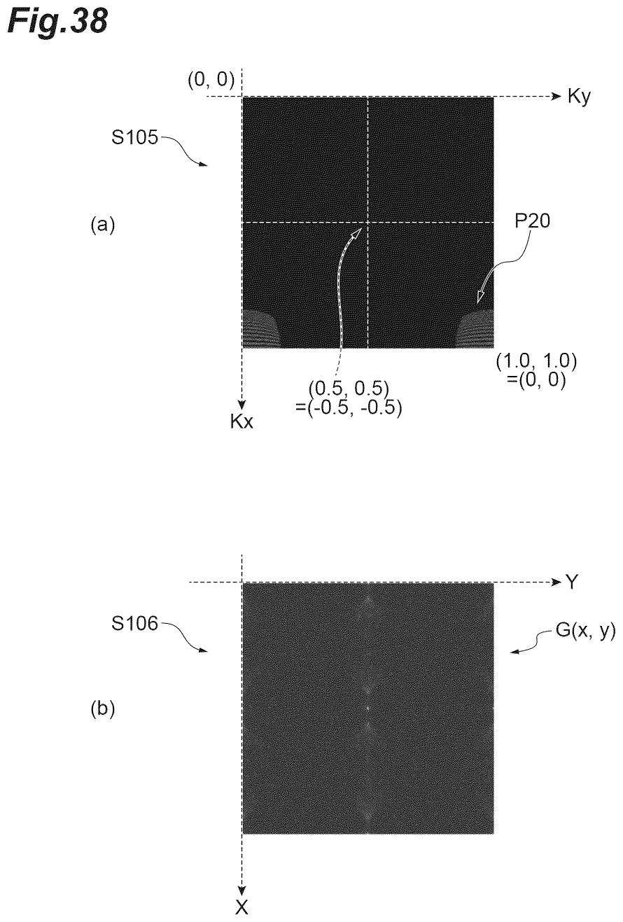

In the manufacturing method according to the present embodiment, after step S104, an inverse Fourier transform is performed on the pattern P20 (FIG. 36(b)) obtained in step S104. Therefore, in the subsequent step, as shown in FIG. 38(a), the quadrants are replaced in advance (step S105). Here, for the pattern P20 shown in FIG. 36, the pattern P20 is folded so that the first quadrant is replaced with the third quadrant and the second quadrant is replaced with the fourth quadrant.

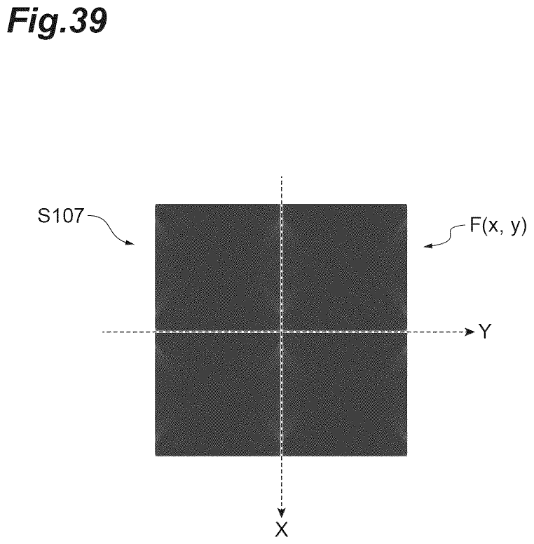

Subsequently, in the manufacturing method according to the present embodiment, as shown in FIG. 38(b), the complex amplitude F(x, y) is calculated by performing a two-dimensional discrete inverse Fourier transform expressed by the above Equation (6) on the new pattern P20 obtained in step S105 (step S106). In addition, at this time, the reproducibility of the beam pattern can also be improved by applying an iterative algorithm, such as a Gerchberg-Saxton (GS) method, which is generally used in calculations for hologram generation. Thereafter, as shown in FIG. 39, the complex amplitude F(x, y) obtained in step S106 is folded so that the third quadrant is replaced with the first quadrant and the fourth quadrant is replaced with the first quadrant (step S107).

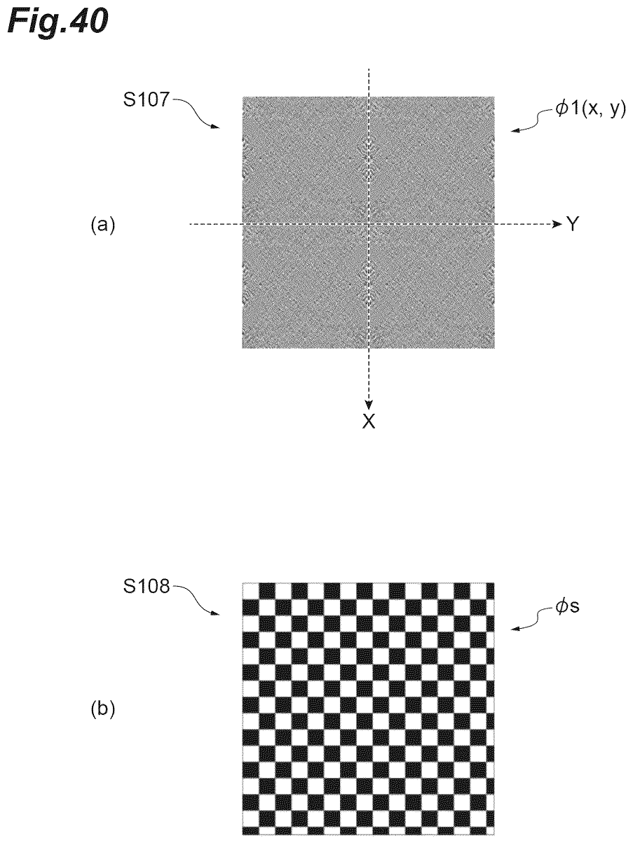

Subsequently, as shown in FIG. 40(a), the rotation angle distribution ϕ₁(x, y), which is a phase distribution, is extracted from the complex amplitude F(x, y) (step S108). As described above, the rotation angle distribution ϕ₁(x, y) is expressed as ϕ₁(x, y)=C×P(x, y)+B using the phase term P(x, y) of the complex amplitude F(x, y). As a method to obtain the intensity distribution and the phase distribution from the complex amplitude distribution obtained by inverse Fourier transform, for example, an intensity distribution I(x, y) can be calculated by using the abs function of MathWorks' numerical analysis software “MATLAB”, and a phase distribution P(x, y) can be calculated by using the MATLAB's angle function.

In the subsequent step, as described above, in order to realize oscillation at the M point, as an example of a specific method for adding the diffraction vector V to the above-described in-plane wave number vectors K6 to K9, the rotation angle distribution ϕ₂(x, y) (second phase distribution) unrelated to the optical image is superimposed on the rotation angle distribution ϕ₁(x, y) (first phase distribution), which is the phase distribution according to the optical image. In this case, the rotation angle distribution ϕ(x, y) of the phase modulation layer 15A is expressed as ϕ(x, y)=ϕ₁(x, y)+ϕ₂(x, y).

ϕ₂(x, y) is a rotation angle distribution for adding the diffraction vector V that satisfies the above Equation (21). Here, as shown in FIG. 40(b), as an example of the rotation angle distribution ϕ₂(x, y), a rotation angle distribution in which the first phase value and the second phase value are arranged in a checkered pattern as in the example of FIG. 18 is prepared (step S108). Assuming that the first phase value is 0 and the second phase value is π, the center direction of the beam matches a direction perpendicular to the plane. Then, by superimposing ϕ₁ and ϕ₂, the rotation angle distribution ϕ(x, y) in the phase modulation layer 15A is obtained. In general, the angle distribution ϕ₂(x, y) of the diffraction vector V is expressed as an inner product between the diffraction vector V(Vx, Vy) and the position vector r(x, y), and is given by the following equation. ϕ₂(x, y)=V·r=Vxx+Vyy. Assuming that the center direction of the beam is a direction perpendicular to the plane, the diffraction vector V needs to cancel out the in-plane wave number vectors K6 to K9 at the M point. For this reason, V=(±π/a, ±π/a). On the other hand, if V is changed from this value, it is possible to emit a beam inclined from the direction perpendicular to the plane.

That is, in this step S108, on the reciprocal lattice space of the phase modulation layer 15A, the in-plane wave number vectors K6 to K9 in the four directions each including a wave number spread corresponding to the angular spread of the optical image are formed, and ϕ(x, y) is constructed by superimposing ϕ₂(x, y) on ϕ₁(x, y) so that the magnitude of at least one of the in-plane wave number vectors K6 to K9 is smaller than 2π/λ.

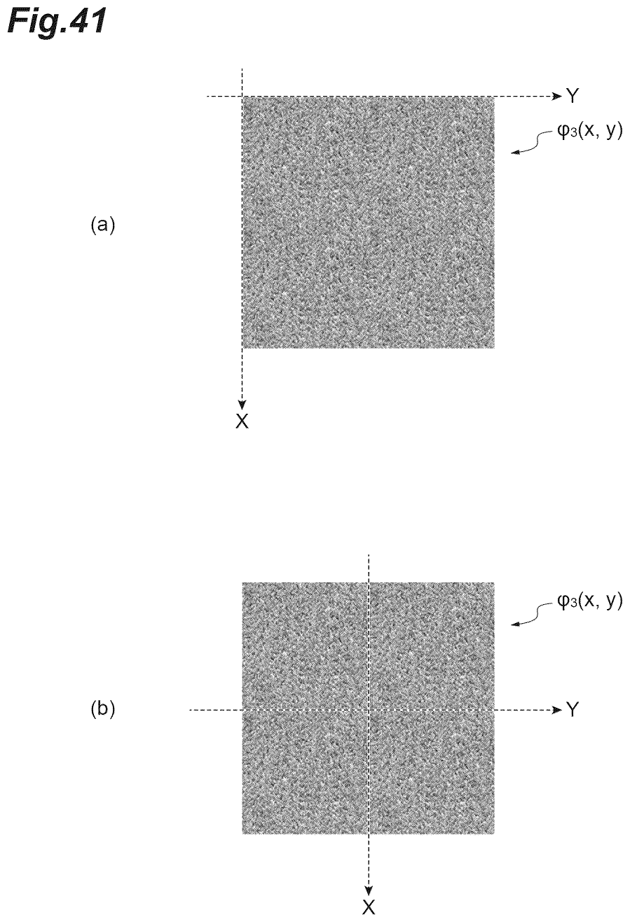

In addition, a rotation angle distribution ϕ₃(x, y) may be acquired from the pattern P20 obtained in step S105 by using the Gerchberg-Saxton (GS) method instead of the inverse Fourier transform in step S106 as shown in FIG. 41(a), and the rotation angle distribution ϕ₃(x, y) may be folded as shown in FIG. 41(b) and then superimposed on ϕ₂(x, y) shown in FIG. 40(b) to calculate ϕ(x, y).

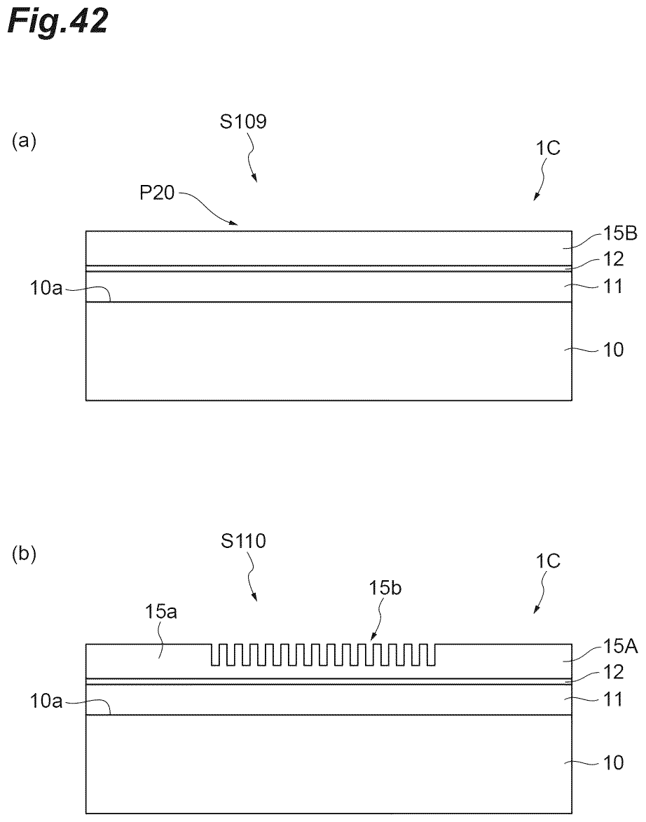

As described above, the rotation angle distribution ϕ(x, y) of the different refractive index region 15b of the phase modulation layer 15A is obtained. In the manufacturing method according to the present embodiment, the phase modulation layer 15A is formed based on the rotation angle distribution ϕ(x, y). In the manufacturing method according to the present embodiment, before forming the phase modulation layer 15A, a semiconductor laminate 1C is prepared as shown in FIG. 42(a). That is, the cladding layer 11, the active layer 12, and the base layer 15a are formed on the main surface 10a of the semiconductor substrate 10. Each compound semiconductor layer can be grown by using the metal organic chemical vapor deposition (MOCVD) method or the molecular beam epitaxy (MBE) method. As described above, in the manufacturing method according to the present embodiment, first, the active layer 12 as a light emitting portion is formed on the semiconductor substrate 10 (step S109: first formation step).

At the same time, the pattern P20 thinned out using the above-described design method is generated, and the rotation angle distribution ϕ(x, y) is calculated (may be calculated in advance) based on the pattern P20. Then, in the manufacturing method according to the present embodiment, the phase modulation layer 15A optically coupled to the active layer 12 is formed based on the rotation angle distribution ϕ(x, y) (step S110: second formation step).

More specifically, in step S110, a resist is applied to the base layer 15a, a two-dimensional fine pattern is drawn on the resist by using an electron beam drawing device, and development is performed to form the two-dimensional fine pattern on the resist. The two-dimensional fine pattern is formed so that the different refractive index regions 15b are distributed according to the rotation angle distribution ϕ(x, y). Thereafter, by using the resist as a mask, the two-dimensional fine pattern is transferred onto the base layer 15a by dry etching to form holes, and then the resist is removed. As a result, the phase modulation layer 15A having the different refractive index region 15b corresponding to the rotation angle distribution ϕ(x, y) is obtained. In addition, a SiN layer or a SiO₂ layer may be formed on the base layer 15a using the PCVD method before forming the resist, a resist mask may be formed on the SiN layer or the SiO₂ layer, a fine pattern may be transferred onto the SiN layer or the SiO₂ layer using reactive ion etching (RIE), and dry etching may be performed after removing the resist. In this case, resistance to dry etching can be improved.

In addition, these holes may be used as the different refractive index regions 15b, or a compound semiconductor (AlGaAs) that becomes the different refractive index region 15b among these holes may be regrown up to a depth equal to or greater than the depth of the holes. When the hole is used as the different refractive index region 15b, a gas such as air, nitrogen, hydrogen, or argon may be filled in the hole. Thereafter, as described above, the cladding layer 13 and the contact layer 14 are sequentially formed by MOCVD, and the electrodes 16 and 17 are formed by using a vapor deposition method or a sputtering method. In addition, if necessary, the protective film 18 and the antireflection film 19 are formed by sputtering, a PCVD method, or the like. As described above, the semiconductor light emitting element 1A is manufactured.

As described above, in the method for designing the phase modulation layer 15A according to the present embodiment, when designing the phase modulation layer 15A of the semiconductor light emitting element 1A that is an iPMSEL, first, a first design pattern (pattern P10), which is a pattern for designing the different refractive index region 15b so that the distribution of the different refractive index region 15b of the phase modulation layer 15A becomes an optical image (pattern P00) output from the semiconductor light emitting element 1A and includes bright spots corresponding to the bright spots of the pattern P00, is generated. Then, by dividing the pattern P10 into a plurality of regions and thinning out at least one of the plurality of bright spots included in each region, a second design pattern (pattern P20) is generated from the pattern P10.

By forming the phase modulation layer 15A based on the pattern P20 generated in this manner, it is possible to reduce noise in the optical image output from the semiconductor light emitting element 1A. One of the reasons for this is thought to be that, by thinning out the bright spots on the design pattern, interference between adjacent bright spots in the actual optical image can be avoided.

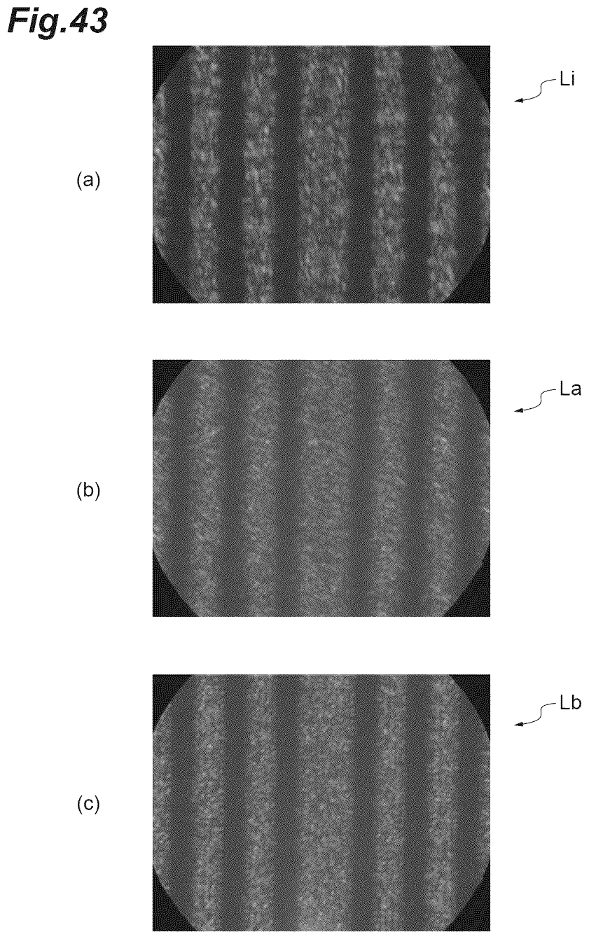

FIG. 43 is a diagram showing a rectangular striped pattern of an optical image output from a semiconductor light emitting element. FIG. 43(a) shows a striped pattern Li of a comparative example when no thinning-out processing is performed on the pattern P10, FIG. 43(b) shows a striped pattern La when the thinning-out in FIG. 37(a) is performed on the pattern P10, and FIG. 43(c) shows a striped pattern Lb when the thinning-out in FIG. 37(b) is performed on the pattern P10. Comparing the striped pattern Li in FIG. 43 with the striped patterns La and Lb, it is understood that in the striped patterns La and Lb, brightness unevenness is suppressed by noise reduction. Actually, assuming that the driving current of the semiconductor light emitting element was 0.5 A, the brightness unevenness was 30.6% in the striped pattern Li, whereas the brightness unevenness was suppressed to 21.8% and 24.3%, respectively, in the striped patterns La and Lb. In addition, the brightness unevenness herein is a value obtained by dividing the standard deviation of brightness values in bright regions with the same area in a rectangular striped pattern by the average value of the brightness values.

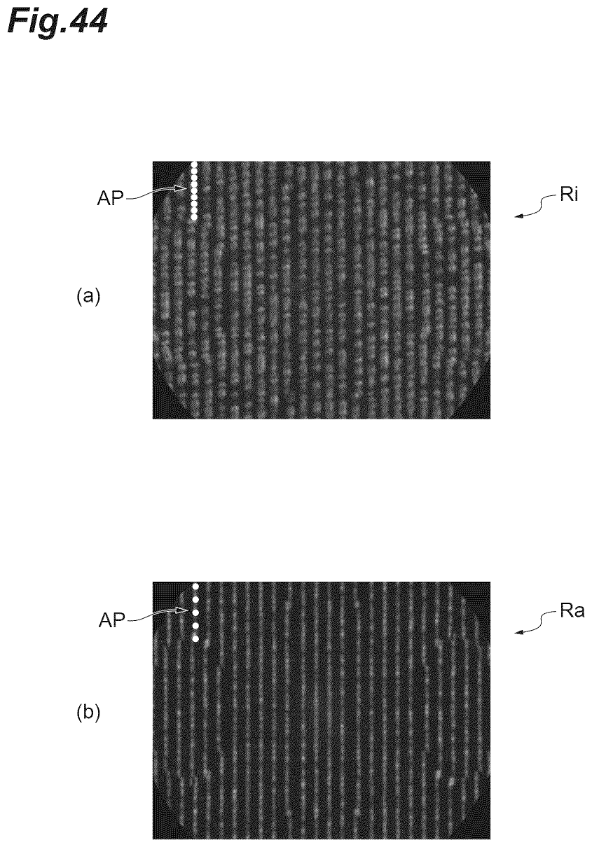

FIG. 44 is a diagram showing a far-field image of light output from a semiconductor light emitting element. In the example of FIG. 44, a desired optical image output from the semiconductor light emitting element 1A is set to a Line & Space pattern. FIG. 44(a) shows a pattern Ri of a comparative example when no thinning-out is performed on the pattern P10, and FIG. 44(b) shows a pattern Ra when thinning-out processing is performed on the pattern P10 point by point. In the pattern Ri, the bright spots AP are densely packed. Therefore, the pattern is blurred due to interference between the bright spots AP, and brightness unevenness also occurs. On the other hand, in the pattern Ra, it is understood that the bright spots AP are spaced apart from each other to suppress interference between the bright spots AP, and as a result, the pattern is sharpened.

In addition, in the method for designing the phase modulation layer 15A according to the present embodiment, the pattern P10 may be a pattern on the wave number space corresponding to the optical image on real space. In step S104, assuming that the wave number data CL indicating four bright spots two-dimensionally adjacent to each other on the wave number space is one region R4, the pattern P20 may be generated by thinning out two of the four pieces of wave number data CL (FIG. 37(a)).

Alternatively, in the method for designing the phase modulation layer 15A according to the present embodiment, the pattern P10 may be a pattern on the wave number space corresponding to the optical image on real space. In step S104, assuming that the wave number data CL indicating four bright spots two-dimensionally adjacent to each other on the wave number space is one region, the pattern 20 may be generated by thinning out three of the four pieces of wave number data CL (FIG. 37(b)). As described above, the pattern P10 can be a pattern on the wave number space corresponding to a desired optical image output from the semiconductor light emitting element 1A. Then, when generating the pattern 20, noise can be reliably reduced by thinning out two or three of the four clustered bright spots (wave number data CL) on the wave number space.

In addition, the method for manufacturing the semiconductor light emitting element 1A according to the present embodiment includes a step S109 of forming the active layer 12 on the semiconductor substrate 10 and a step S110 of generating the pattern P20 using the above-described method for designing the phase modulation layer 15A and forming the phase modulation layer 15A optically coupled to the active layer 12 based on the pattern P20. Therefore, a light emitting element capable of reducing noise is manufactured.

In addition, in the method for manufacturing the semiconductor light emitting element 1A according to the present embodiment, when a virtual square lattice is set in the XY plane, the first design pattern is generated so that the center of gravity G of each different refractive index region 15b is arranged away from the corresponding lattice point O and has a rotation angle ϕ according to the phase distribution corresponding to the optical image around the lattice point O and the lattice spacing a of the virtual square lattice and the emission wavelength λ satisfy the conditions for M-point oscillation.

In addition, in the method for manufacturing the semiconductor light emitting element 1A, on the reciprocal lattice space of the phase modulation layer 15A, the in-plane wave number vectors K6 to K9 in the four directions each including a wave number spread corresponding to the angular spread of the optical image are formed, the rotation angle distribution ϕ₂(x, y) is superimposed on the rotation angle distribution ϕ₁(x, y) so that the magnitude of at least one of the in-plane wave number vectors K6 to K9 is smaller than 2π/λ, and the phase modulation layer 15A including a plurality of different refractive index regions 15b is formed by using the rotation angle distribution ϕ(x, y) obtained by the superimposition. Therefore, it is possible to remove 0th-order light from the optical image output from the light emitting element.

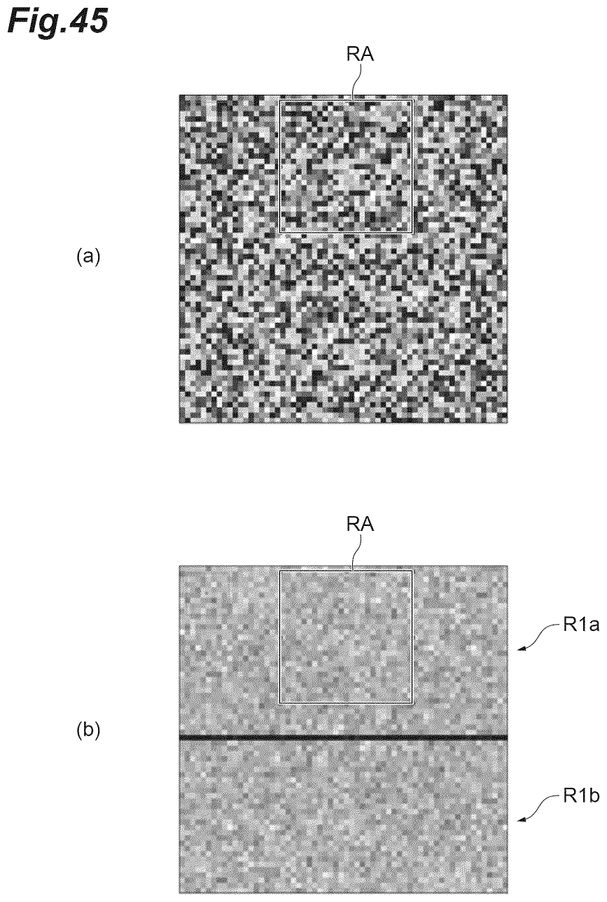

In addition, as shown in FIG. 45(b), in the method for designing the phase modulation layer 15A, in steps S101 to S103 of generating the pattern P10, a design region Ria corresponding to the 1st-order light of the optical image and a design region Rib corresponding to the −1st-order light of the optical image may be separated from each other in the pattern P10. In this case, noise can be reduced more reliably.

FIG. 45(a) shows a pattern P10 when the 1st-order light and the −1st-order light are not separated from each other, and FIG. 45(b) shows a pattern P10 when the 1st-order light and the −1st-order light are separated from each other. When the 1st-order light and the −1st-order light are not separated from each other, the standard deviation of the brightness values within a region RA is 0.305. On the other hand, when the 1st-order light and the −1st-order light are separated from each other, the standard deviation of the brightness values within the region RA is 0.072. Therefore, it is understood that the brightness unevenness is reduced. It is thought that the reduction in brightness unevenness in the pattern P10 leads to noise reduction in the optical image. In addition, in the example of FIG. 45, the desired optical image output from the semiconductor light emitting element 1A is set in a rectangular pattern.

The embodiment described above is examples of the method for designing a phase modulation layer and a method for manufacturing a semiconductor light emitting element according to the present disclosure, and may be modified as desired. For example, a desired optical image is not limited to the striped pattern of a sinusoidal wave or a rectangular wave or the Line & Space pattern, and can be set to any pattern. In addition, processing for M-point oscillation or separation between the 1st-order light and the −1st-order light is not essential.

### REFERENCE SIGNS LIST

1A: semiconductor light emitting element (light emitting element), 12: active layer (light emitting portion), 15A: phase modulation layer, 15a: base layer, 15b: different refractive index region, AP: bright spot, P00: pattern (optical image), P10: pattern (first design pattern), P20: pattern (second design pattern), R1a, R1b: design region, R4: region.

1: A method for designing a phase modulation layer of a light emitting element as an iPMSEL including a light emitting portion and the phase modulation layer optically coupled to the light emitting portion, the method comprising:
a generation step for generating a design pattern of the phase modulation layer,
wherein the phase modulation layer includes a base layer and a plurality of different refractive index regions having different refractive indices from the base layer and distributed two-dimensionally in a plane perpendicular to a thickness direction of the phase modulation layer, and
the generation step includes:
a first step of generating a first design pattern that is a pattern for designing the different refractive index regions so that a distribution of the different refractive index regions becomes a distribution according to an optical image output from the light emitting element and that includes bright spots corresponding to bright spots of the optical image; and
a second step of generating a second design pattern from the first design pattern by dividing the first design pattern generated in the first step into a plurality of regions and thinning out at least one of a plurality of bright spots included in each of the regions.

2: The method for designing a phase modulation layer according to claim 1,
wherein the first design pattern is a pattern on a wave number space corresponding to the optical image, and
in the second step, four bright spots two-dimensionally adjacent to each other on the wave number space are set as the one region, and the second design pattern is generated by thinning out two of the four bright spots.

3: The method for designing a phase modulation layer according to claim 1,
wherein the first design pattern is a pattern on a wave number space corresponding to the optical image, and
in the second step, four bright spots two-dimensionally adjacent to each other on the wave number space are set as the one region, and the second design pattern is generated by thinning out three of the four bright spots.

4: The method for designing a phase modulation layer according to claim 1,
wherein, in the first step, in the first design pattern, a design region corresponding to 1st-order light of the optical image and a design region corresponding to −1st-order light of the optical image are separated from each other.

5: A method for manufacturing a light emitting element, comprising:
a first formation step for forming a light emitting portion on a substrate; and
a second formation step for forming a phase modulation layer optically coupled to the light emitting portion based on the second design pattern generated by the method for designing a phase modulation layer according to claim 1.

6: The method for manufacturing a light emitting element according to claim 5,
wherein, in the first step, when a virtual square lattice is set in the plane, the first design pattern is generated so that a center of gravity of each of the different refractive index regions is arranged away from a corresponding lattice point and has a rotation angle according to a phase distribution corresponding to the optical image around the lattice point and a lattice spacing a of the virtual square lattice and an emission wavelength λ of the light emitting portion satisfy conditions for M-point oscillation, and
in the second formation step, on a reciprocal lattice space of the phase modulation layer, in-plane wave number vectors in four directions each including a wave number spread corresponding to an angular spread of the optical image are formed, another second phase distribution is superimposed on a first phase distribution as the phase distribution so that a magnitude of at least one of the in-plane wave number vectors is smaller than 2π/λ, and the phase modulation layer including the plurality of different refractive index regions is formed by using a phase distribution obtained by the superimposition.
